(19) United States
(12) Patent Application Publication
(10) Pub. No.: US 2012/0325314 A1
(43) Pub. Date: Dec. 27, 2012

(54) Solar Power Collection Using High-Focus-Accuracy Mirror Array

(75) Inventors: Patrick C. Cheung, Castro Valley, CA (US); Patrick Y. Maeda, Mountain View, CA (US)

(73) Assignee: Palo Alto Research Center Incorporated, Palo Alto, CA (US)

(21) Appl. No.: 13/166,775

(22) Filed: Jun. 22, 2011

(51) Int. Cl. H01L 31/0232; F24J 2/04; F03G 6/06; F24J 2/38

(52) U.S. Cl. 136/259; 126/600; 126/574; 126/576; 126/634; 60/641.11

(57) ABSTRACT

A method for harvesting solar power by concentrating sunlight onto a raised solar receiver disposed on a tower. The method involves rotating a mirror array made up of multiple flat mirrors as a unit around a vertical axis such that sunlight shines on the mirror array from a fixed apparent azimuth angle at all times during daylight hours, and controlling each mirror's pivot position to track the sun's elevation angle such that sunlight is accurately reflected onto the raised solar receiver at all times during daylight hours. In one embodiment the mirror array is disposed on a roundabout-type platform whose rotational position is controlled to track the sun's azimuth angle and the raised receiver is maintained at a substantially fixed position relative to the mirror array for all rotational positions of the platform.

### FIELD OF THE INVENTION

The present invention relates generally to an improvement in solar-power generation, and more particularly to an improved method for harvesting (collecting) solar power.

### BACKGROUND OF THE INVENTION

State of the art solar-tower plants use approximately one thousand heliostat mirrors each on 2-axis trackers to reflect sunlight onto a receiver placed on the top of a tower. Each heliostat typically includes an array of flat (or in slightly concave) mirrors that are maintained in a substantially upright position on a support post. A total reflective surface area per heliostat of greater than 100 m² (e.g., approximately 150 m²) is not uncommon. Each mirror in the array (heliostat field) is pivoted (rotated) in two axes to track the apparent angular movement of the sun such that exiting (reflected) sunlight is constantly directed from the mirrors onto the raised solar receiver during daylight hours. A prominent example is the PS20 plant near Seville, Spain, which is built by Abengoa Solar from the same sunny European country. PS20 produces 20 MegaWatts of electricity from collecting sunlight from 1,255 heliostats, with each heliostat having a flat mirror surface area of 1,291 square feet. Across the Atlantic, heliostat development effort in the U.S. was initiated in 1975. Since then, solar-tower plant (system) designers have determined that it is more economical to build larger heliostats which in turn will service plants with larger power output. These plants are very promising as a renewable power source because the LCOS (Levelized Cost of Energy) is near 6 to 7/kWhr, which falls somewhere between the U.S. retail rates of 10/kWhr and generation cost from fossil fuel plants of 3/kWhr. Cost subtotal of heliostats makes up 50% of the total cost of a solar-tower plant, and current technology can only bring the cost of heliostat to near $126/m².

The solar-tower industry has to overcome a number of technical challenges to bring future cost of heliostats to below $100/m², at which point experts believe that the solar-tower technology will be competitive on the open market, especially if carbon-offset trading becomes the norm. The per-square-meter figure is the metric commonly used for comparison. The actual cost of a heliostat is the per-meter figure multiplied to the area of the mirror, and currently is in the neighborhood of $18,000 each.

One impediment to reducing the cost of conventional heliostats is that the upright mirror arrangement experiences significant wind loading that must be accounted for by the mirror frame and support post. Conventional large heliostats utilize flat mirrors having reflective surface areas of approximately 150 m². This arrangement provides an advantage when the sun's elevation is low, for example, in the early morning, in that the large heliostats are able to catch sunlight that otherwise reaches the ground outside the operation's boundary. However, in windy conditions, the upright mirror arrangement effectively forms a large wind sail, and the resulting wind load forces are transmitted through the mirror support frame to the support post (which acts as a mast). Unless the support frame and support post structures are engineered to withstand worst case wind conditions, they risk damage or complete failure (collapse) under worst-case wind conditions. Thus, each heliostat's support frame and support post structures must either be extensively engineered, resulting in high design and production costs, or the heliostats will be subject to periodic wind-related damage, resulting in high repair and/or replacement costs. Replacing a large mirror with many small mirrors that add up to the same reflective area typically requires each small mirror be pivoted with two motors, and that has shown to be more costly. Furthermore, enough space between mirrors must be allocated for cleaning, maintenance, and collision avoidance, causing a reduction in reflective surface area.

Sometimes there are reasons to produce power on a smaller scale. For example, smaller plants near a city can provide electricity with quicker response and less loading on the grid. A 2 MW plant can supply electricity to 1,000 homes in the vicinity, and with cogeneration capability, can use super-heated steam from a solar collection system to drive a turbine when sunlight is available, or burn natural gas to drive the same turbine at night to provide round-the-clock electricity production. Land utilization and land cost become crucial design parameters in this scenario, which is a scenario that has been overlooked in power-tower developments in the past thirty years. Given availability of new technologies, new production methods, current power requirements, and the exigency of global warming, it is meaningful to give another look to systems that can steer thousands of small mirrors to plants that are in the proximity of 2 MW to find a design that is more economical and perhaps higher performing than the status quo.

In a different type of small scale operation, large-sized upright heliostats are placed on the top of a tall commercial building. Although this arrangement provides advantages in the reduction of land use, such an arrangement is problematic in that it may be costly to reinforce existing building structures to secure a retrofitted large heliostat against high winds.

What is needed is an improved solar-tower generation system that addresses the cost and scalability (to scale down) issues associated with conventional solar-tower systems.

### SUMMARY OF THE INVENTION

The present invention is directed to a solar-tower system and solar energy harvesting method in which a mirror array comprising multiple relatively small flat mirrors disposed in a low-profile (i.e., substantially horizontal two-dimensional plane) pattern are rotated as a unit around an axis in a manner that tracks the sun's azimuth angle, and a tilt angle of each flat mirror of the mirror array is controlled to track the sun's elevation angle such that each flat mirror accurately reflects sunlight beams onto a raised solar receiver, which is maintained in a fixed position relative to the mirror array for all rotational positions of the mirror array. In comparison to conventional solar-tower arrangements, the present invention greatly simplifies the operation of reflecting sunlight onto the raised solar receiver with a high degree of accuracy because, by rotating the mirror array around an axis to track the sun's azimuth angle in accordance with the present invention, the turntable continues to bring each mirror of the mirror array into a position that receives the sunlight from a fixed apparent azimuth angle at all times during daylight hours. Because each mirror receives sunlight from the fixed apparent azimuth angle, and because the raised solar receiver is maintained in a fixed position relative to each mirror, the only adjustment necessary to continuously redirect sunlight onto the raised solar receiver during daylight hours is adjustment of the mirror's tilt angle to account for the sun's changing elevation angle, which is accomplished by rotating the mirror around its predetermined unique pivot axis. By providing higher accuracy of the reflected sunlight, the present invention facilitates the use of a large number (e.g., hundreds or thousands) of smaller mirrors (e.g., having a reflective area of 10 m² or less) and corresponding smaller solar receivers in order to facilitate efficient conversion of substantially all available solar power to usable energy in a way that greatly reduces total manufacturing costs over those associated with conventional solar-tower arrangements. In addition, by restricting the sun's apparent azimuth angle throughout the day, a large number of mirrors can be packed (i.e., closely spaced) and arranged with minimal shadowing and blocking in order to generate highly concentrated sunlight on the raised solar receiver, thereby generating higher temperatures (e.g., 500° C. or higher) using a smaller area than can be achieved by conventional solar-tower arrangements. Moreover, by maintaining each mirror of the mirror array in a low profile, substantially horizontal plane, the present invention avoids the wind-loading issues associated with conventional heliostats using upright mirror arrangements, thereby greatly reducing engineering constraints and corresponding production costs of the solar-tower system, and facilitating the production of smaller systems that can be placed, for example, on the top of high-rise buildings.

According to an aspect of the invention, the rotational position of the mirror array around the rotational axis is controlled by a solar azimuth tracking controller such that the mirrors receive sunlight from the fixed apparent azimuth angle at all times during daylight hours. To facilitate rotation of the mirror array as a unit, in one embodiment the multiple flat mirrors are fixedly connected to a support structure using associated support mechanisms, wherein the solar azimuth tracking controller is operably connected to rotate the support structure around a centrally located rotational axis. In an exemplary embodiment the support structure comprises a circular or square roundabout platform supported on wheels that are constrained to move along a curved (e.g., circular or semi-circular) guide (e.g., rail or track) around the central axis, and the solar azimuth tracking controller includes one or more sensors for detecting the sun's azimuth angle, a processor for generating control signals in response to the detected azimuth angle, and a motor that is operably coupled to the roundabout platform and responsive to the control signals to rotate the roundabout platform into alignment with the detected sun's azimuth angle. At dawn the solar azimuth tracking controller detects the rising sun and generates control signals that cause the base structure to rotate such that each mirror of the mirror array faces eastward such that the rising sun is positioned in the desired fixed apparent azimuth angle relative to the mirror array. During the day, as the sun's azimuth angle tracks from east to west, the solar azimuth tracking controller generates control signals that cause the base structure to rotate accordingly such that the sun remains in the desired fixed apparent azimuth angle relative to the mirror array. With this arrangement, the entire mirror array is rotated into the fixed apparent azimuth angle using a simple, rather slow, and low cost azimuth tracking controller that requires minimal energy, thereby facilitating much higher energy output than is possible using conventional solar-tower arrangements while maintaining low system costs.

According to another aspect of the invention, each mirror of mirror array is constrained to pivot rotate around a single rotational axis, and a solar elevation tracking controller is provided for controlling the pivot positions of an individual mirror or a group of mirrors in accordance with the sun's elevation angle such that sunlight received by each mirror is accurately reflected onto the raised solar receiver at all times during daylight hours. In an exemplary embodiment the rotational axis of each mirror comprises a solid axle including a drive member (e.g., a gear or pulley), and the solar elevation tracking controller includes one or more sensors for detecting the sun's elevation angle, a processor for generating control signals in response to the detected elevation angle, and a motor that is operably coupled to the drive member and responsive to the control signals to rotate the mirror around its axis and into the correct position to reflect sunlight onto the raised solar receiver. In particular, at dawn the solar elevation tracking controller individually causes each mirror to rotate into a corresponding tilt position in accordance with the sun's lower elevation angle such that each mirror is properly positioned to accurately reflect its received sunlight along a predetermined reflection angle onto the raised solar receiver. During the late morning hours, as the sun's elevation angle increases, the solar elevation tracking controller generates control signals that cause each mirror to tilt upward into a corresponding tilt position that such that the reflected sunlight is directed along a predetermined reflection angle that coincides with the raised solar receiver. Subsequently, during the afternoon hours, as the sun's elevation angle decreases, the solar elevation tracking controller generates control signals that cause the mirrors to tilt downward. Because the base structure rotates such that the sunlight is directed on each mirror from a fixed apparent azimuth angle, the function performed by solar elevation tracking controller is greatly simplified, thereby facilitating the concentration of sunlight from multiple mirrors onto a single raised solar receiver with minimal operating cost and complexity.

According to an aspect of the present invention, the mirrors of the mirror array are arranged in a predetermined pattern (e.g., in rows and columns) on the support structure, and the orientation and pivot axis assigned to each mirror of mirror array are unique for that mirror and are determined in accordance with the mirror's position relative to the raised solar receiver. In an exemplary embodiment, the placement and alignment of the unique axis for each mirror is found by determining three ideal mirror orientations (tilt positions at which ideal beams directed along three associated sun angles are reflected from the center of the mirror onto a center of the raised solar receiver, then computing two error vectors based on vectors extending normal (perpendicular) to the mirror in each of the three mirror orientations, and then computing a cross product of the two error vectors to determine the mirror axis. An angled bracket is then provided that rotatably connects the mirror to the platform by way of the support mechanisms such that, as the mirror rotates around the computed axis, the mirror assumes each of the three ideal mirror orientations. With this arrangement, the solar elevation tracking controller is able to accurately reflect sunlight rays directed along a predetermined fixed apparent azimuth angle from each mirror onto the raised solar receiver simply by individually controlling each mirror's pivot position in accordance with the sun's elevation angle.

According to an embodiment of the present invention, multiple mirrors (e.g., mirror disposed in each row or each column of the mirror array) are connected by a common power transfer mechanism (e.g., a drive shaft) to a motor disposed on the roundabout platform. According to an aspect of the invention, the gear set associated with each mirror is connected to the drive shaft by way of a gear mechanism having a unique gear ratio determined in accordance with the mirror's position relative to the raised solar receiver, whereby a group of mirrors driven from a single actuation will result in different angles of rotations, each angle of rotation being optimized for transferring sunlight to the raised solar receiver. The benefit of this arrangement is that the large number of small mirrors in the mirror array are driven by a relatively small number of motors (i.e., a small fraction of the total number of mirrors), thereby avoiding the high cost of driving each mirror using a separate motor. Note that in such an embodiment a mirror's pivot angle is constrained by two factors: the orientation of the rotational axis thus chosen, and a specific angle of the mirror that couples to other mirrors connected to the same drive shaft as they are pivoted to their corresponding specific angles. In a specific embodiment, the optimal angle of rotation for each mirror is determined by determining the ideal deviation angles of the mirror for multiple sun elevation angles ranging from 0° to 90° (such as 19 angles at 5° interval each), summing the deviation angles, and then minimizing the sum as a function of gear ratio R.

According to alternative embodiments of the present invention, the raised solar receiver is disposed on a tower that extends above the upper surface of the base structure (i.e., above the mirror array). In one arrangement, the tower is an elongated structure that extends along (i.e., collinear with) the rotational axis defining the center of rotation of the mirror array, thereby maintaining the raised solar receiver substantially on the rotational axis for all rotational angles of the mirror array. In one specific embodiment, the tower is fixedly mounted on the base structure such that the raised solar receiver rotates at the same rate as the mirror array. In another specific embodiment, the tower is fixedly attached to the same support surface that supports the base structure such that the base structure rotates relative to the tower and the raised solar receiver. In yet another specific embodiment, a plurality of towers are fixedly attached to the base structure away from the rotational axis. Each of these arrangements maintains the raised solar receiver in a substantially fixed position relative to all of the mirrors for all rotational angles of the mirror array, thereby facilitating more efficient transfer of solar energy to the raised solar receiver than is possible using conventional solar-tower systems.

In accordance with yet another set of alternative embodiments, the base structure comprises either a single platform, or is formed as two or more platforms that are disposed to rotate as a group around the rotational axis, e.g., on a set of concentric rails, where each platform carries a subset of the mirror array in the manner described above and can rotate as well. The multiple platform approach addresses possible cost and engineering drawbacks associated with utilizing a single large platform to support the entire mirror array. This multiple platform approach may also be manipulated to facilitate access roads to move equipment or electricity in and out of the surrounding mirrors. That is, one of the platforms can be removed from a ring-shaped pattern to open a space for an access path to the centrally located tower, although the access path itself will have to move while the rest of the platforms move.

In accordance with an alternative embodiment of the present invention, the solar receiver comprises a conduit containing a heat transfer fluid that is transmitted from the solar receiver to an external heat exchange system (e.g., a steam turbine). In one specific embodiment, the external heat exchange system is part of a co-generation power plant utilizing both the solar-tower system of the present invention and a conventional natural gas heat generator to generate steam for driving a turbine. The solar-tower system is disposed in a 100 meter by 100 meter area next to the steam production facility, and is used to produce steam during daylight hours. At night (or on cloudy days when solar energy is insufficient), the natural gas heat generator is implemented to generate steam. The solar-tower systems of the present invention are ideally suited for use in such co-generation power plant arrangements because they combine a clear set of upfront costs, low land use, low maintenance costs, and highly reliable performance expectations.

In accordance with yet another alternative embodiment, the solar receiver comprises a device (e.g., a photovoltaic (PV) cell or a thermoelectric cell) that directly converts the concentrated solar energy into electricity that is then transmitted by conductive wire to a designated load. This arrangement is conducive to implementing the solar-tower system using a smaller platform and mirror array that can be mounted, for example, on a residential rooftop. The roundabout platform configuration minimizes wind disturbance, can operate on slanted rooftops, and potentially can be lighter (less demanding to withstand wind) and cheaper to build. The strength of the platform design is also its weakness. Since it stays flat on the ground, the basic design cannot present the maximum mirror area to the sun when the sun's elevation is low. In an alternative embodiment, the platform can be tilted to a fixed tilt angle that will allow maximum mirror area to be presented to the sun. When wind picks up, the platform can be lowered to the horizontal position but continue to track and produce electricity although at a lower output (that is consistent with the sun having a lower elevation position).

### BRIEF DESCRIPTION OF THE DRAWINGS

These and other features, aspects and advantages of the present invention will become better understood with regard to the following description, appended claims, and accompanying drawings, where:

FIG. 1 is a top front perspective view showing a solar-tower system according to a simplified embodiment of the present invention;

FIG. 2 is a simplified side elevation view showing a roundabout platform support mechanism utilized in accordance with an embodiment of the present invention;

FIGS. 3(A) and 3(B) are top plan views showing rotation of roundabout platform support mechanism of FIG. 2 by an exemplary solar azimuth tracking controller according to an exemplary embodiment of the present invention;

FIG. 4 is a simplified top side perspective view showing a solar elevation tracking controller according to an exemplary embodiment of the present invention;

FIGS. 5(A) and 5(B) are side elevation views showing pivoting of flat mirrors of the system of FIG. 1 by an solar elevation tracking system according to an exemplary embodiment of the present invention;

FIGS. 6(A), 6(B) and 6(C) are simplified top side perspective views showing the solar-tower system of FIG. 1 during operation;

FIG. 7 is a simplified top plan view showing an incomplete solar-tower system according to a specific embodiment of the present invention;

FIG. 8 is a flow diagram showing a method for assembling the solar-tower system of FIG. 7 according to a specific embodiment of the present invention;

FIGS. 9(A), 9(B) and 9(C) are simplified rear top perspective views showing a mirror of the solar-tower system of FIG. 7 in three orientations according to the method of FIG. 8;

FIGS. 10(A), 10(B) and 10(C) are simplified side views showing the mirror in the orientations of FIGS. 9(A), 9(B) and 9(C), respectively;

FIGS. 11(A) and 11(B) are vector diagrams illustrating the computation of a pivot axis for the mirror of FIGS. 9(A)-9(C) using the method of FIG. 8;

FIG. 12 is a simplified rear top perspective view showing the mirror of FIGS. 9(A)-9(C) with an angled bracket produced in accordance with an embodiment of the present invention;

FIG. 13 is a simplified top plan view showing the solar-tower system of FIG. 7 with the mirror of FIGS. 9(A)-9(C) mounted on a platform in accordance with an embodiment of the present invention;

FIG. 14 is a simplified partial top front perspective view showing two mirrors of the system of FIG. 13 with gear sets determined in accordance with the method of FIG. 8;

FIGS. 15(A) and 15(B) are simplified side views showing solar-tower systems according to alternative specific embodiment of the present invention;

FIG. 16 is a simplified top plan view showing a solar-tower system according to another alternative specific embodiment of the present invention;

FIG. 17 is a simplified top plan view showing a solar-tower system according to another alternative specific embodiment of the present invention;

FIG. 18 is a simplified diagram showing a cogeneration power system including a solar-tower system of the present invention according to another alternative specific embodiment of the present invention; and

FIG. 19 is a simplified top plan view showing a solar-tower system according to another alternative specific embodiment of the present invention.

### DETAILED DESCRIPTION OF THE DRAWINGS

The present invention relates to an improved solar-tower system. The following description is presented to enable one of ordinary skill in the art to make and use the invention as provided in the context of a particular application and its requirements. As used herein, directional terms such as “upper”, “upwards”, “lower”, “downward”, “front”, “rear”, are intended to provide relative positions for purposes of description, and are not intended to designate an absolute frame of reference. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

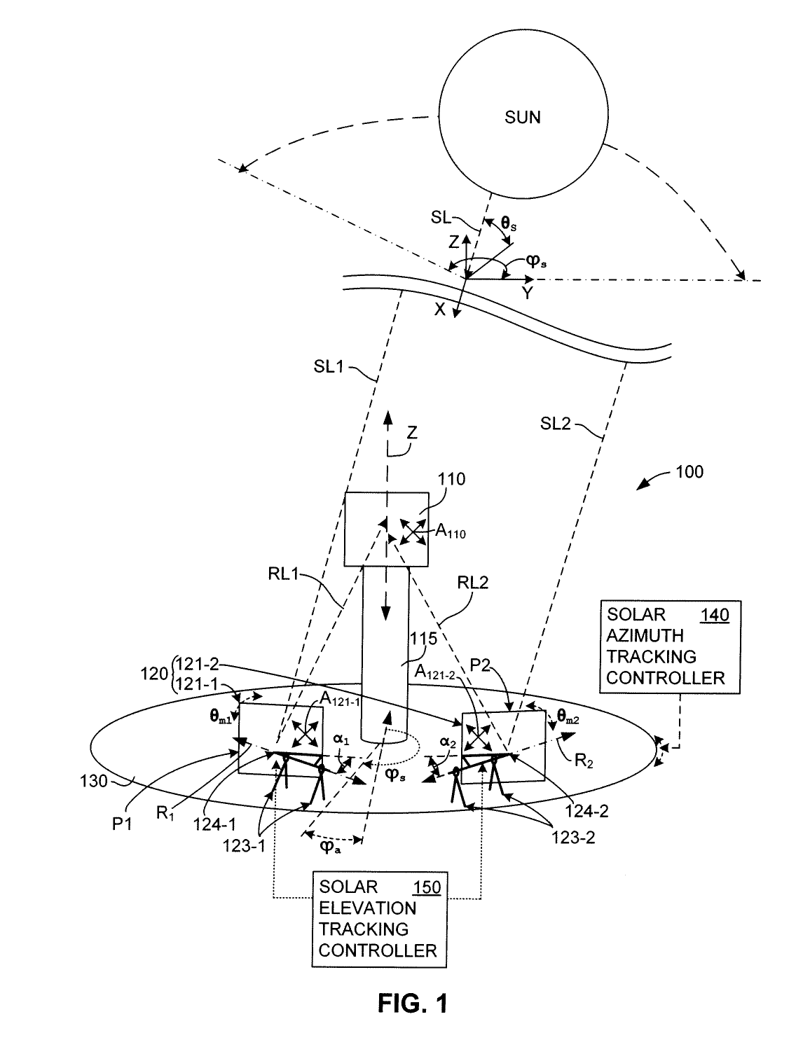

FIG. 1 is a simplified perspective diagram showing a generalized solar-tower system 100 according to a simplified embodiment of the present invention. Similar to conventional solar-tower arrangements, system 100 includes a raised solar receiver 110 (e.g., disposed on a tower 115) and a mirror array 120 including multiple flat mirrors (e.g., mirrors 121-1 and 121-2) that are controlled to redirect corresponding parallel sunlight rays (indicated by dashed-line arrows SL1 and SL2) onto solar receiver 110. Note that only two mirrors (i.e., mirrors 121-1 and 121-2, which are illustrated with their planar reflective surfaces P1 and P2 facing into the drawing sheet) are shown in FIG. 1 for exemplary purposes and that, as set forth below, practical applications of the present invention utilize tens, hundreds or even thousands of mirrors.

According to a first aspect of the invention, all mirrors of mirror array 120 are maintained in a fixed arranged such that rotation of mirror array 120 around a common rotational axis Z causes every mirror (e.g., mirrors 121-1 and 121-2) to rotate as a unit around a common rotational axis Z. In one embodiment, each mirror of mirror array 120 is mounted by way of a support mechanism in a predetermined position on a carousel-type base structure 130. For example, as shown in the exemplary embodiment shown in FIG. 1, mirror 121-1 is mounted on support mechanism 123-1 that is fixedly connected to base structure 130, and mirror 121-2 is mounted on support mechanism 123-2 that is also fixedly connected to base structure 130. With this arrangement, all of the mirrors of mirror array 120 are rotated as a unit when base structure 130 is rotated around common axis Z. As used herein, the phrase “rotated as a unit” means that all of the mirrors maintain their predetermined fixed position relative to each other when mirror array 120 is rotated around axis Z (e.g., when base structure 130 is around axis Z, mirrors 121-1 and 121-2 are simultaneously rotated around axis Z due to their fixed connection to base structure 130 by way of support mechanisms 123-1 and 123-2, respectively). Note that the phrase “rotated as a unit” does not require each mirror to remain “frozen” at its predetermined fixed position in that each mirror is tiltable (pivotable) as described below.

According to another aspect of the invention, all mirrors of mirror array 120 are fixedly arranged in a low-profile pattern for all rotational positions of array 120. That is, all mirrors of mirror array 120 (e.g., mirrors 121-1 and 121-2) are maintained (e.g., by support mechanisms 123-1 and 123-2) at a predetermined minimal distance above an underlying support surface (e.g., base structure 130) that allows the tilt/pivot operations discussed below, but otherwise maintains all of the mirrors of mirror array 120 in a substantially horizontal plane. Because the mirror array 120 is maintained in a low-profile horizontal plane, the heliostat 100 of the present invention avoids the wind-loading issues associated with conventional heliostats using upright mirror arrangements, thereby greatly reducing engineering constraints and corresponding production costs of the heliostat 100. That is, because the mirrors of mirror array 120 are maintained in a low-profile horizontal plane, the present invention avoids the significant windload forces experienced by upright mirror arrangements, and can therefore be manufactured using construction techniques that are much less expensive that those required for upright mirror arrangements.

According to another aspect of the invention, each mirror of mirror array 120 is oriented and constrained (i.e., held such that movement is limited) to pivot around a corresponding unique pivot axis such that sunlight can be reflected onto raised solar receiver 110 at all times during daylight hours. For example, mirror 121-1 is constrained by support mechanisms 123-1 to rotate around a pivot axis R₁, and is oriented such that, for any given sun elevation angle, there is a corresponding pivot angle θₘ₁ of mirror 121-1 around pivot axis R₁ that causes incident sunlight SL1 to be reflected from planar reflective surface P1 such that reflected sunlight RL1 is directed onto raised solar receiver 110. Similarly, mirror 121-2 is oriented and constrained by support mechanism 123-2 to rotate around a pivot axis R₂ into corresponding pivot angles θₘ₂ that causes incident sunlight SL2 to be reflected from planar reflective surface P2 such that reflected sunlight RL2 is directed onto raised solar receiver 110. Note that the directions of reflected sunlight portions RL1 and RL2 are not the same, and as such the orientation and pivot axis positions of mirrors 121-1 and 121-2 are necessarily different due to their different locations on base structure 130. Moreover, because two mirrors cannot occupy the same location, the orientation and pivot axis of each mirror in mirror array 120 is unique (i.e., different from all other mirrors in mirror array 120). As indicated in FIG. 1, in a preferred embodiment, the mirror orientation and pivot axis of each mirror are determined using a novel technique such that the straight line defining the pivot axis forms an acute orientation angle with the planar reflective surface of each mirror (i.e., the pivot axis of each mirror is not parallel to the mirror's reflective surface). For example, as shown in FIG. 1, pivot axis R₁ forms an orientation angle α₁ with reference to planar reflective surface P1 of mirror 121-1, and pivot axis R₂ forms an acute angle α₂ with reference to planar reflective surface P2 of mirror 121-2. In one embodiment, the corresponding mirror orientation and pivot axis of each mirror is maintained by way of a rigid angular bracket. For example, mirror 121-1 is connected to support mechanism 123-1 by way of an angled bracket 124-1 having a first portion secured to a back surface of mirror 121-1 and a second portion extending along pivot axis R₁, and mirror 121-2 is connected to support mechanism 123-2 by way of an angled bracket 124-2 having a first portion secured to a back surface of mirror 121-2 and a second portion extending along pivot axis R₂. Further details regarding pivot axis determination and the construction of the angled brackets are set forth below.

According to yet another aspect of the invention, each mirror of mirror array 120 has a flat reflective surface that is substantially equal in size (i.e., within 10%) and shape to the surface area of the sunlight-receiving surface of raised solar receiver 110. For example, as indicated in FIG. 1, raised solar receiver 110 has a rectangular sunlight-receiving surface having a surface area A₁₁₀, and mirrors 121-1 and 121-2 respectively include planar rectangular reflective surfaces P1 and P2 (both facing into the sheet) having reflective surface areas R₁₂₁₋₁ and R₁₂₁₋₂ that are respectively substantially equal to or slightly smaller than surface area A₁₁₀. Setting reflective surface areas A₁₂₁₋₁ and A₁₂₁₋₂ of square flat mirrors 121-1 and 121-2 at 10 m² size, square mirrors 121-1 and 121-2 would measure 3.2 meters on the side. Receiver surface area A₁₁₀ should be at least the size of mirrors 121-1 and 121-2 plus approximately 0.3 meters on each side. The latter is to account for the fact that the sun is not a point source, instead, its sheer size amounts to +/−0.25 degrees around the incident angle and therefore the farthest mirror will project an area on the receiver which is that much larger. The practical minimum size of receiver has to account for focus errors of all the mirrors if there is to be no wasted sunlight due to spillage. Thus, if focus error is kept under one meter or so, the receiver need not be much larger; whereas if a mirror array design yields focus errors that are on the order of the mirror's length (of 3.2 meters) then the receiver size has to be doubled, which increases system costs.

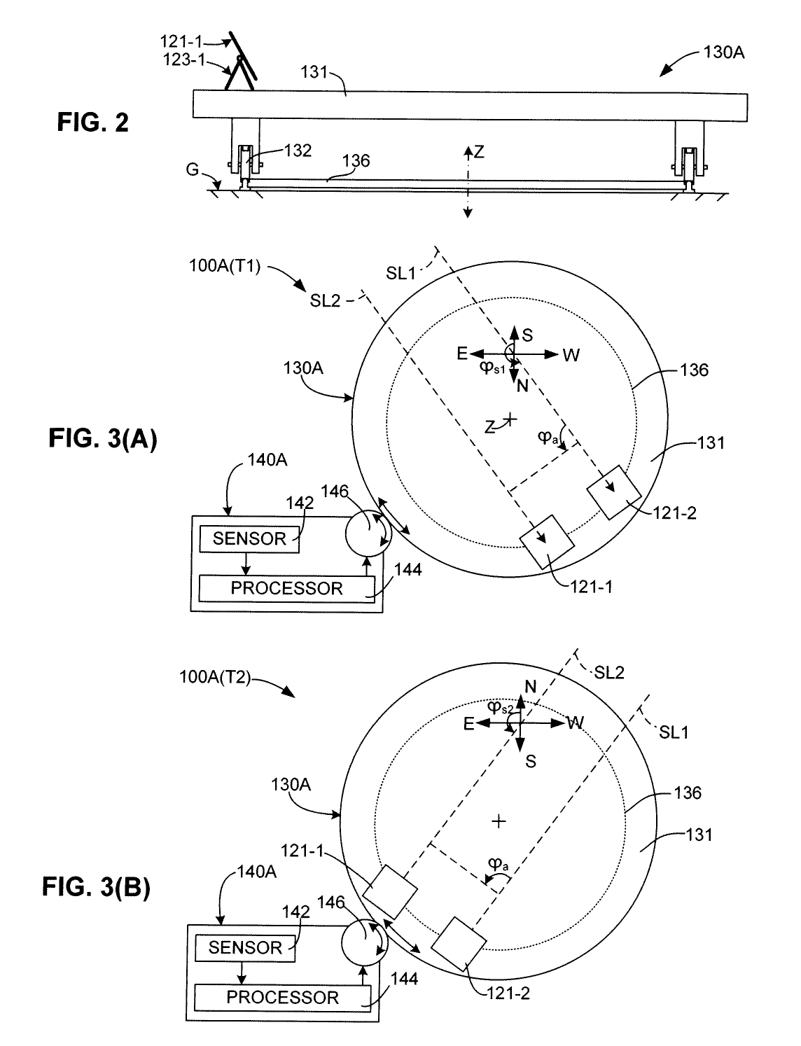

FIG. 2 is a partial side view showing a base support 130A according to simplified exemplary embodiment of the present invention. Base structure 130A is constructed in a manner similar to well-known roundabout platform arrangements utilized, for example, in the railroad industry, and includes a flat (e.g., square or disc-shaped) roundabout platform 131 that is movably supported by wheels 132 that are engaged with a curved guide 136 (e.g., a circular or semi-circular rail or track whose center coincides with axis Z), which in turn is fixedly attached to an underlying support surface (e.g., ground G). Every mirror of mirror array 120 (e.g., mirror 121-1, shown in FIG. 2) is fixedly attached to platform 131 by way of a corresponding support mechanism (e.g., support mechanism 123-1). This arrangement constrains base support 130 to rotate around centrally located axis Z, which in this embodiment extends perpendicular to the underlying support surface (e.g., base structure 130 is positioned over flat horizontal ground G, and axis Z is vertically aligned). Those skilled in the art will recognize that the specific base structure arrangement shown in FIG. 2 is merely exemplary, and that several alternative arrangements may be utilized to achieve functions of the rotating base structures described herein.

Referring again to side of FIG. 1, according to another aspect of the invention, a solar azimuth tracking controller 140 controls a rotational position of mirror array 120 around an axis Z in accordance with the sun's azimuth angle φₛ such that mirror array 120 continuously receives sunlight from a fixed apparent azimuth angle φₐ at all times during daylight hours. As indicated in the upper portion of FIG. 1, the sun's azimuth angle φₛ is measured in a horizontal (e.g., X-Y) plane relative to a fixed position, and continuously changes (e.g., from east to west) during the daylight hours of each day. In one embodiment, solar azimuth tracking controller 140 serves to gradually (i.e., either continuously or periodically in small increments) change the rotational position of mirror array 120 by rotating base structure 130 around an axis Z.

FIGS. 3(A) and 3(B) are simplified top views showing a portion of system 100A during morning and evening time periods, respectively. In the exemplary embodiment shown in these figures, a solar azimuth tracking controller 140A includes a sensor 142 for detecting the sun's azimuth angle, a processor 144 for generating generate control signals in accordance with the output of sensor 142, and motor 146 that is operably connected to a peripheral edge of base support 130A such that motor 146 causes roundabout platform 131 of base support 130A to rotate on circular track 136 around axis Z (shown in end view) in accordance with the control signals generated by processor 144. FIG. 3(A) shows system 100A(T1) (i.e., system 100A at a time T1, e.g., at sunrise) when the sun is positioned such that the azimuth angle φₛ₁ of sunlight rays SL1 and SL2 is directed in a generally southeast-to-northwest direction. According to an embodiment of the present invention, solar azimuth tracking controller 140A causes base support 130A to rotate around axis Z such that each mirror 121-1 and 121-2 faces southeast toward the rising sun, and in particular such that sunlight rays SL1 and SL2 are directed along a fixed apparent azimuth angle φₐ onto mirrors 121-1 and 121-2 (e.g., at a right angle to the upper/lower edge of each mirror, as indicated in FIG. 3(A)). During the day, as the sun's relative position changes from southeast to southwest, solar azimuth tracking controller 140A causes base structure 130A to rotate accordingly such that the sun remains in the desired fixed apparent azimuth angle φₐ relative to mirrors 121-1 and 121-2. FIG. 3(B) shows system 100A(T2) (i.e., system 100A at a time T2, e.g., in the evening) when the sun is positioned such that the azimuth angle φₛ₂ of sunlight rays SL1 and SL2 is directed in a generally southwest-to-northeast direction, and solar azimuth tracking controller 140A positions base support 130A such that mirrors 121-1 and 121-2 face southwest toward the setting sun with sunlight rays SL1 and SL2 directed along the same fixed apparent azimuth angle φₐ onto mirrors 121-1 and 121-2. With this arrangement, the entire mirror array is rotated into the fixed apparent azimuth angle φₐ using a simple, low cost azimuth tracking controller that requires minimal energy, thereby facilitating much higher energy output than is possible using conventional solar-tower arrangements while maintaining low system costs. Those skilled in the art will recognize that solar azimuth tracking controller 140A of FIGS. 3(A) and 3(B) is merely exemplary, and that several alternative arrangements may be utilized to achieve functions of that solar azimuth tracking controllers described herein. For example, the rotation of base support 130A may be determined by stored data instead of in accordance with detected positions of the sun.

Referring again to FIG. 1, according to another aspect of the present invention, a tilt (pivot) position of each flat mirror of mirror array 120 (e.g., mirrors 121-1 and 121-2) around its corresponding unique pivot axis (e.g., pivot axes R₁ and R₂) is controlled by a solar elevation tracking controller 150 such that each said flat mirror is selectively pivoted into a corresponding pivot angle that reflects sunlight rays SL1 and SL2 onto raised solar receiver 110 in accordance with the sun's changing elevation angle θₛ throughout the daylight hours. As indicated in the upper portion of FIG. 1, the sun's elevation angle θₛ is measured in a vertical (e.g., X/Y-Z) plane relative to a fixed position, and continuously changes (i.e., rises from the horizon to a high point at midday, then sinks back to the horizon in the evening) during the daylight hours of each day. As shown in FIG. 1, mirror 121-1 is supported on support structure 123-1 such that mirror 121-1 can be pivoted around its associated pivot axis R₁, whereby the flat reflective surface of mirror 121-1 pivots into a selected corresponding pivot angle θₘ₁ to reflect light onto raised solar receiver 110. Similarly, mirror 121-2 is supported on support structure 123-2 such that mirror 121-2 can be pivoted around axis R₂, whereby mirror 121-1 pivots into a selected corresponding pivot angle θₘ₂ to reflect light onto raised solar receiver 110. As indicated by the dashed-line arrows in FIG. 1 and described further below, solar elevation tracking controller 150 controls the pivot angles θₘ₁ and θₘ₂ of each mirrors 121-1 and 121-2, respectively, in accordance with a current sun elevation angle such that sunlight rays SL1 and SL2 are reflected by mirrors 121-1 and 121-2, respectively, onto raised solar receiver 110 at all times during daylight hours.

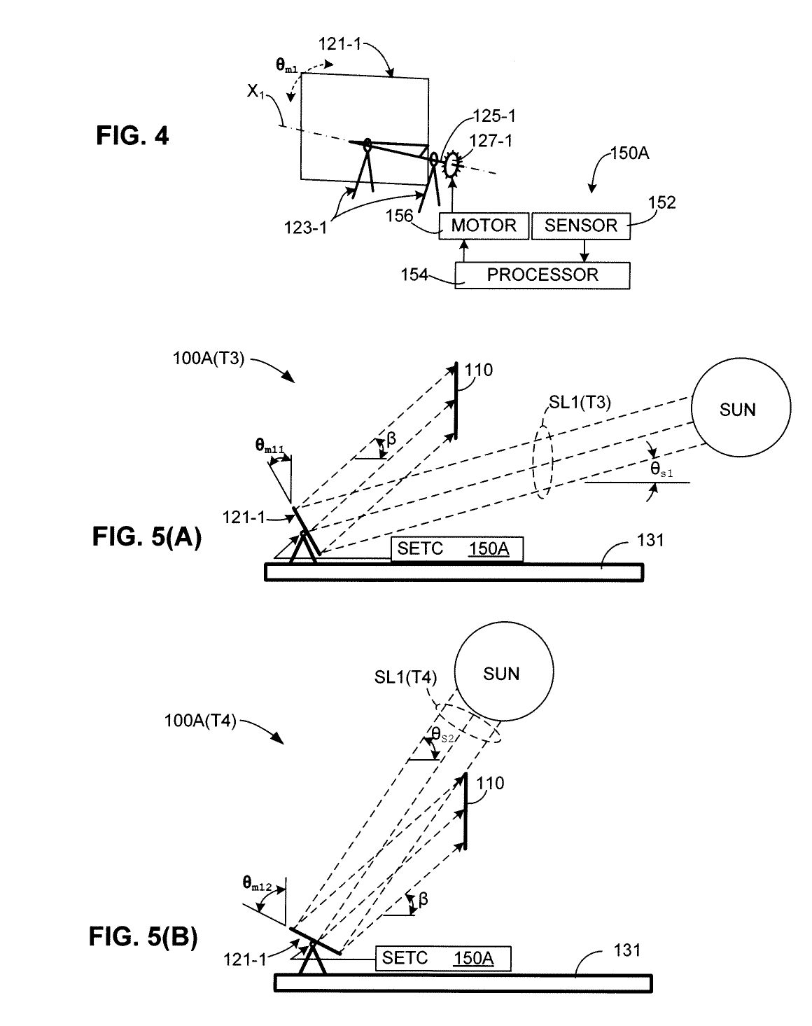

FIG. 4 is a partial perspective view showing a mirror 121-1 and an exemplary solar elevation tracking controller 150A according to a specific embodiment of the present invention. In this exemplary embodiment, the rotational axis R₁ of mirror 121-1 includes a solid axle 125-1 fixedly connected to a drive member 127-1 (e.g., a gear or pulley), and solar elevation tracking controller 150A includes one or more sensors 152 for detecting the sun's elevation angle, a processor 154 for generating control signals in response to the detected elevation angle, and a motor 156 that is operably coupled to the drive member 127-1 and responsive to the control signals to rotate the mirror 121-1 around its axis R₁ and into the correct position to reflect sunlight onto the raised solar receiver. This arrangement constrains mirror 121-1 to pivot around axis R₁ in accordance with rotation of motor 156. Those skilled in the art will recognize that the specific arrangement shown in FIG. 4 is merely exemplary, and that several alternative arrangements may be utilized to achieve the mirror rotation functions described herein.

FIGS. 5(A) and 5(B) are simplified side views showing a portion of solar-tower system 100A including platform 131 and mirror 121-1 during morning/evening and midday time periods, respectively. FIG. 5(A) shows solar-tower system 100A(T3) (i.e., solar-tower system 100A at dawn or in the evening) when the sun's elevation angle θₛ₁ is relatively shallow due to the sun's low position on the horizon. During these periods, solar elevation tracking controller (SETC) 150A generates control signals that cause mirror 121-1 to rotate into pivot angle θₘ₁₁ such that mirror 121-1 is properly positioned to reflect sunlight rays SL1(T3) at a predetermined reflection angle β onto raised solar receiver 110. FIG. 5(B) shows solar-tower system 100A(T4) (i.e., solar-tower system 100A during midday hours) after the sun's elevation angle elevation angle θₛ₂ has increased to a maximum elevation. To track the elevation angle change from angle θₛ₁ (see FIG. 5(A)) to angle θₛ₂, solar elevation tracking controller continuously or periodically generates control signals that cause mirror 121-1 to gradually tilt backward into pivot angle θₘ₁₂ to reflect sunlight rays SL1(T2) at predetermined reflection angle β onto raised solar receiver 110. Subsequently, during the afternoon hours as the sun's elevation angle again decreases, the solar elevation tracking controller generates control signals that cause mirror 121-1 to tilt downward toward pivot angle θₘ₁₁.

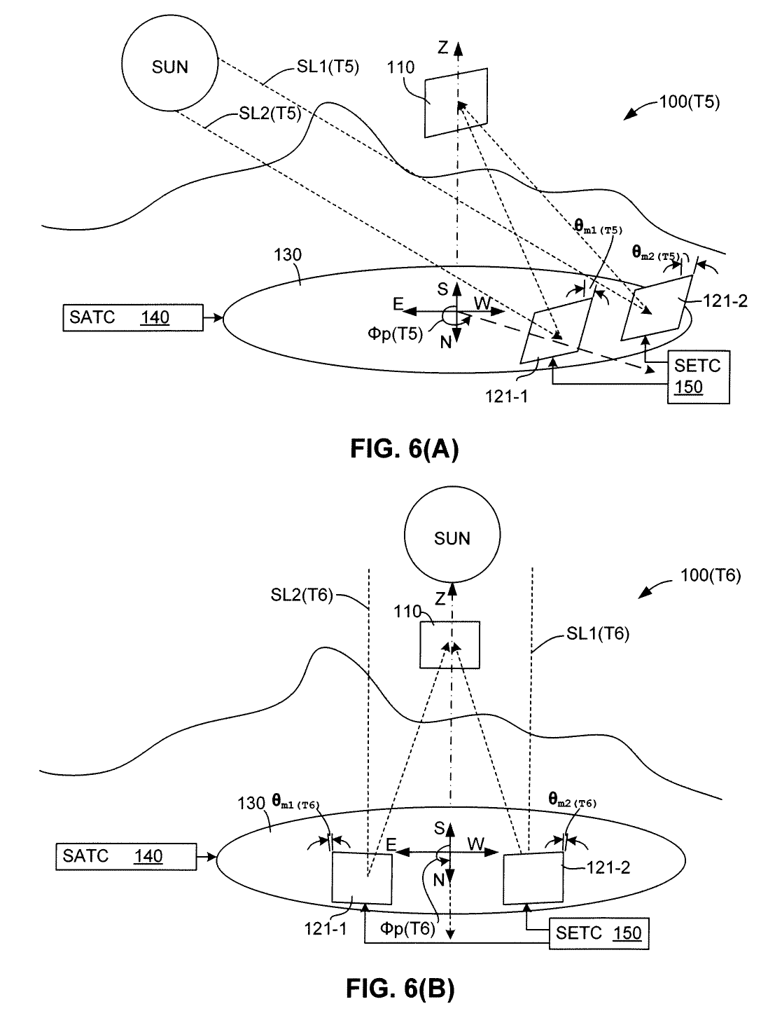

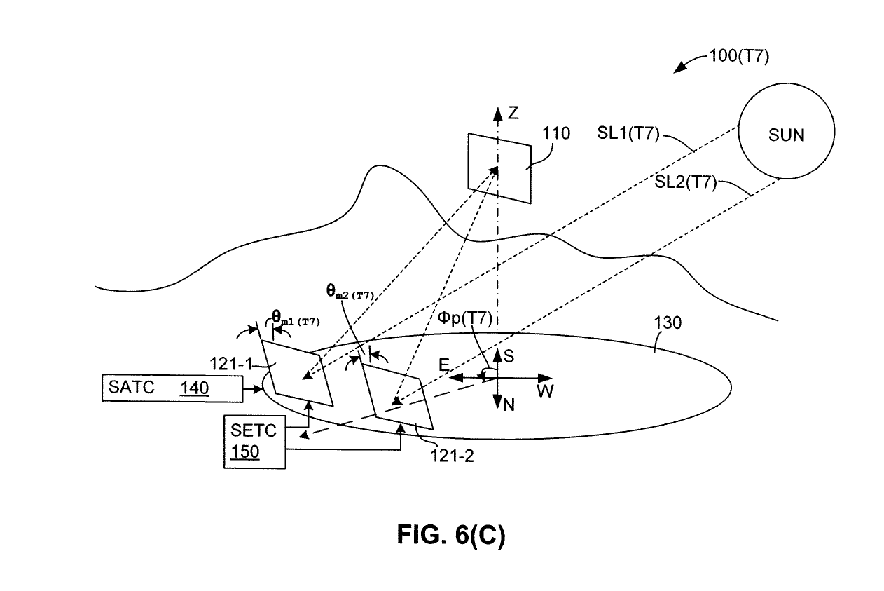

FIGS. 6(A) to 6(C) are simplified diagrams illustrate the operation of solar-tower system 100 during the course of a typical day, and in particular show the simultaneous operation of both solar azimuth tracking controller (SATC) 140 and solar elevation tracking controller (SETC) 150A to maintain sunlight reflected from mirrors 121-1 and 121-2 on solar receiver 110. FIG. 6(A) shows solar-tower system 100(T5) (i.e., solar-tower system 100 at dawn) at the beginning of daylight hours when the sun is positioned such that the azimuth angle of sunlight rays SL1 and SL2 is directed in a generally southeast-to-northwest direction and the sun's elevation angle is relatively shallow due to the sun's low position on the horizon. In accordance with the present invention, at time T5, solar azimuth tracking controller 140 positions base support 130 in a first position φ_{p(T5)} such that sunlight rays SL1(T5) and SL2(T5) are directed along a predetermined fixed apparent azimuth angle onto mirrors 121-1 and 121-2, and solar elevation tracking controller 150 positions mirrors 121-1 and 121-2 in pivot angles θ_{m1(T5)} and θ_{m2(T5)} such that sunlight rays SL1(T5) and SL2(T5) are reflected at predetermined reflection angles onto raised solar receiver 110. FIG. 6(B) shows solar-tower system 100(T6) (e.g., solar-tower system 100 at noon) when the sun is positioned such that the azimuth angle of sunlight rays SL1 and SL2 is directed in a generally south-to-north direction and the sun's elevation angle is at its highest point. In accordance with the present invention, between times T5 and T6, solar azimuth tracking controller 140 causes base support 130 to gradually or continuously rotate around axis Z such that sunlight rays SL1 and SL2 remain directed along the predetermined fixed apparent azimuth angle onto mirrors 121-1 and 121-2, whereby at time T6, solar azimuth tracking controller 140 positions base support 130 in a second position φ_{p(T6)}. Simultaneously, between times T5 and T6, solar elevation tracking controller 150 causes mirrors 121-1 and 121-2 to gradually or continuously tilt back around their corresponding tilt axes such that sunlight rays SL1 and SL2 remain accurately reflected onto raised solar receiver 110, whereby at time T6, solar elevation tracking controller 150 positions mirrors 121-1 and 121-2 in pivot angles θ_{m1(T6)} and θ_{m2(T6)} such that sunlight rays SL1(T6) and SL2(T6) are reflected onto raised solar receiver 110. FIG. 6(C) shows solar-tower system 100(T7) (e.g., solar-tower system 100 in the evening) when the sun is positioned such that the azimuth angle of sunlight rays SL1 and SL2 is directed in a generally southwest-to-northeast direction and the sun's elevation angle has again dropped to a lower point. In accordance with the present invention, between times T6 and T7, solar azimuth tracking controller 140 causes base support 130 to gradually or continuously rotate around axis Z such that sunlight rays SL1 and SL2 remain directed along the predetermined fixed apparent azimuth angle onto mirrors 121-1 and 121-2, whereby at time T7, solar azimuth tracking controller 140 positions base support 130 in a third position φ_{p(T7)}. Simultaneously, between times T6 and T7, solar elevation tracking controller 150 causes mirrors 121-1 and 121-2 to gradually or continuously tilt forward around their corresponding tilt axes such that sunlight rays SL1 and SL2 remain accurately reflected onto raised solar receiver 110, whereby at time T6, solar elevation tracking controller 150 positions mirrors 121-1 and 121-2 in pivot angles θ_{m1(T7)} and θ_{m2(T7)} such that sunlight rays SL1(T7) and SL2(T7) are reflected onto raised solar receiver 110.

As exemplified in the example illustrated in FIGS. 6(A) to 6(C) (described above), solar-tower system 100 includes a mirror array including flat mirrors 121-1 and 121-2 that are rotated as a unit around rotational axis Z in a manner that tracks the sun's azimuth angle, and tilt angles θₘ₁ and θₘ₂ of flat mirrors 121-1 and 121-2 are controlled to track the sun's elevation angle such that flat mirrors 121-1 and 121-2 respectively accurately reflect sunlight beams SL1 and SL2 onto raised solar receiver 110, which is maintained in a fixed position (e.g., by way of a tower) relative to the mirror array for all rotational positions φₚ of the mirror array 120. In comparison to conventional solar-tower arrangements, the present invention greatly simplifies the operation of reflecting sunlight onto raised solar receiver 110 with a high degree of accuracy because, by rotating the mirror array 120 around axis Z to track the sun's azimuth angle in accordance with the present invention, each mirror 121-1 and 121-2 receives the sunlight from a fixed apparent azimuth angle φₐ at all times during daylight hours. Therefore, because raised solar receiver 110 is maintained in a fixed position relative to each mirror 121-1 and 121-2, the only adjustment necessary to continuously redirect sunlight beams SL1 and SL2 onto receiver 110 during daylight hours is adjustment of tilt angles θₘ₁ and θₘ₂ to account for the sun's changing elevation angle, which is accomplished by rotating mirrors 121-1 and 121-2 around pivot axes R₁ and R₂ (shown in FIG. 1). By providing higher accuracy of the reflected sunlight, the present invention facilitates the use of a large number (e.g., hundreds or thousands) of smaller mirrors (e.g., having a reflective area of 10 m² or less) and corresponding smaller solar receivers in order to facilitate efficient conversion of substantially all available solar power to usable energy in a way that greatly reduces total manufacturing costs over those associated with conventional solar-tower arrangements. In addition, by restricting the sun's apparent azimuth angle throughout the day, as illustrated in FIGS. 6(A) to 6(C), a large number of mirrors can be arranged with minimal shadowing and blocking in order to generate highly concentrated sunlight on the raised solar receiver, thereby generating higher temperatures (e.g., 500° C. or higher) using a smaller area than can be achieved by conventional solar-tower arrangements.

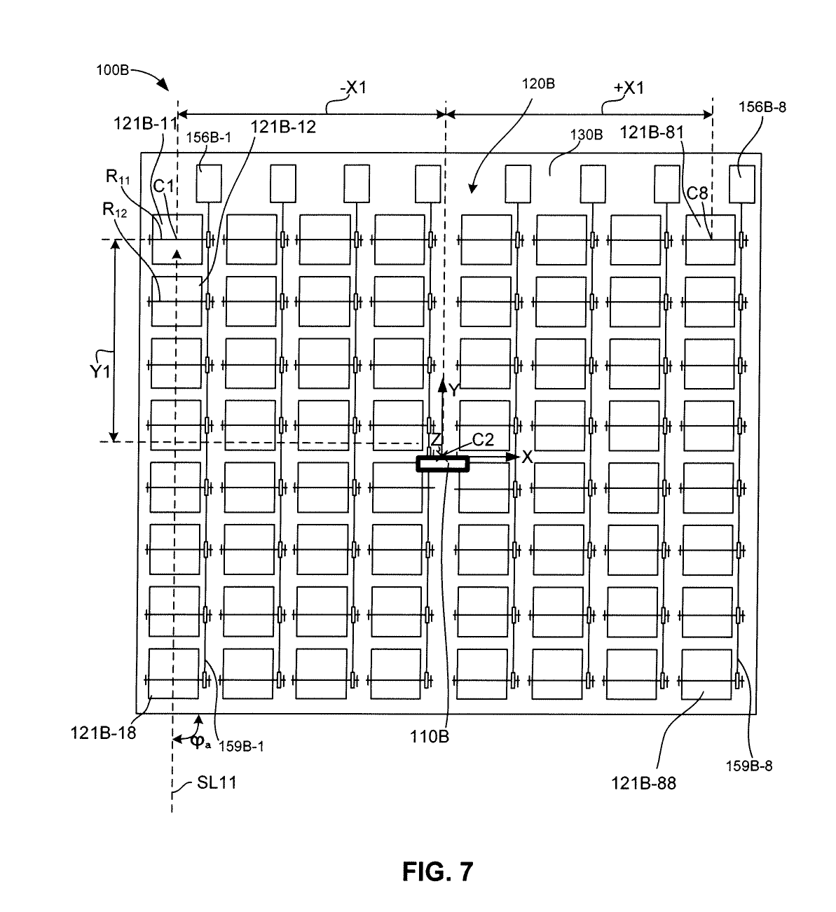

FIG. 7 is a simplified top view showing an incomplete simplified solar-tower system 100B. Solar-tower system 100B generally includes including a mirror array 120B made up of mirrors 121B-11 to 121B-88 disposed on a support structure 130B, and a raised solar receiver 110B disposed over array 120B in a manner similar to that described above. In this exemplary embodiment, flat mirrors 121B-11 to 121B-88 of mirror array 120B are arranged in a predetermined rows and columns pattern, where each column of mirrors includes mirrors aligned in a first (Y-axis) direction (e.g., the vertical line of mirrors in FIG. 7 including mirrors 121B-11 to 121B-18 form a first column, and the vertical line of mirrors including mirrors 121B-81 to 121B-88 form a second column), and where each row of mirrors includes mirrors aligned in a second (X-axis) direction that is orthogonal to the first direction (e.g., the horizontal line of mirrors in FIG. 7 including mirrors 121B-11 to 121B-81 form a first row, and the vertical line of mirrors including mirrors 121B-18 to 121B-88 form a second row).

As depicted in FIG. 7, solar-tower system 100B is considered incomplete because mirrors 121B-11 to 121B-88 are shown prior to determination and adjustment of their corresponding unique orientation and axis in order to reflect sunlight onto receiver 110B. As indicated in the upper left corner of FIG. 7, if tilt axis R11 of mirror 121B-11 was parallel with the tilt axes of all remaining mirrors 121B-12 to 121B-88, sunlight ray SL11 directed along a predetermined fixed apparent azimuth angle φₐ would be reflected essentially parallel to the column including mirror 121B-11 (i.e., sunlight ray SL11 would not be reflected at the proper angle needed for reflection onto raised solar receiver 110B). Therefore, according to a feature of the embodiment shown in FIG. 7, in order for solar-tower system 100B to operate in a manner similar to that described above with reference to FIGS. 6(A)-6(C), a unique pivot axis and a unique mirror orientation is determined (e.g., calculated using the method described below) for each mirror, and each mirror is pivotably mounted on base structure 130B in accordance with its determined unique pivot axis and a unique mirror orientation so that all of mirrors 121B-11 to 121B-88 can be pivoted around their unique pivot axes by an elevation tracking controller (not shown) into corresponding ideal sunlight reflecting positions at any point during the daylight hours.

According to an embodiment of the present invention, the rotational axis and mirror orientation of each mirror in mirror array 120B are determined in accordance with the unique X-axis, Y-axis and Z-axis location of each mirror's center relative to the center of raised solar receiver 110B. For example, a center point C1 of mirror 121B-11 is positioned at coordinates −X1 and Y1 from a center region C2 of receiver 110B, and is also positioned at a Z-axis distance (measured perpendicular to the drawing sheet) from center region C2. Accordingly, the orientation of mirror 121B-11 and tilt axis R11 are determined in accordance with the process described below to account for the unique X/Y/Z location of center C1 of mirror 121B-11 relative to center C2 of receiver 110B, whereby sunlight ray is reflected properly onto raised solar receiver 110B throughout the daylight hours. Note that a center region C8 of mirror 121B-18 is positioned at the same Y-axis and Z-axis distances from center region C2 of receiver 110B, but is located at a different X-axis location (+X1), so the orientation and tilt axis of mirror 121B-18 are necessarily different from those of mirror 121B-11. In a similar fashion, because no two mirrors of mirror 121B-11 to 121B-88 occupy the same X-, Y- and Z-axis location, the determined orientation and pivot axis of each mirror 121B-11 to 121B-88 is necessarily unique.

According to another feature of the embodiment depicted in FIG. 7, groups of mirrors (e.g., mirrors disposed in each row or each column of a mirror array) are connected by a common power transfer mechanism to a motor disposed on the base structure, and the tilt angle of each mirror in the group of mirrors is controlled by a single actuation transmitted from the motor by way of the drive mechanism. For example, FIG. 7 shows that the mirrors in each column (e.g., mirrors 121B-11 to 121B-18 and mirrors 121B-81 to 121B-88) are connected by common power transfer mechanisms (e.g., drive shafts 159B-1 and 159B-8) to corresponding motors (e.g., motors 156B-1 and 156B-8) that are fixedly connected to roundabout platform 131B of base structure 130B. In this example, the rotation of a large number of mirrors (i.e., mirrors 121B-11 to 121B-88) is actuated by a relatively small number of motors (i.e., motors 156B-1 to 156B-8). By moving the entire mirror array using a small number of motors and tracking systems, the present invention significantly reduces system costs.

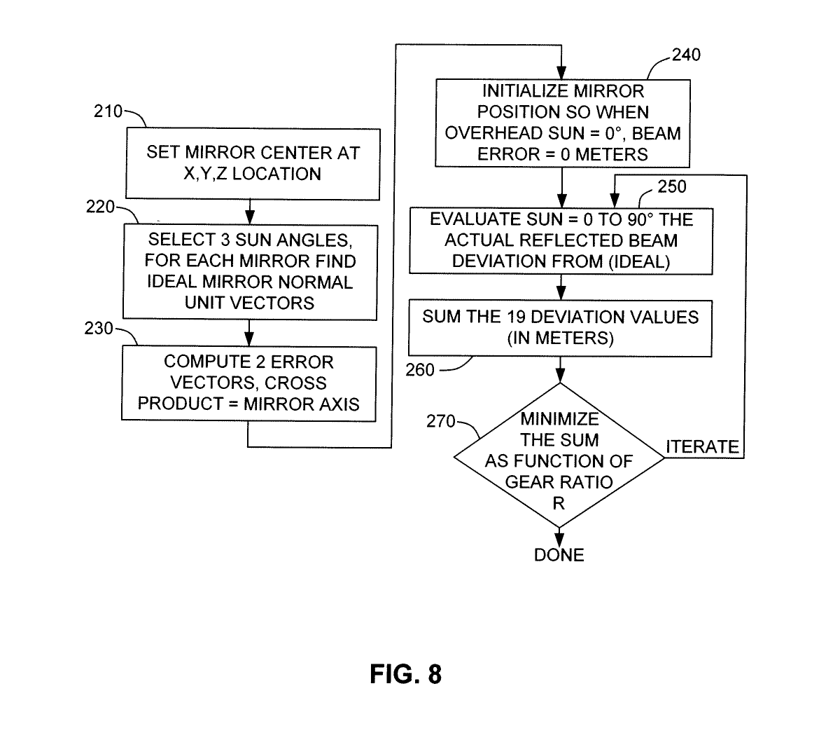

FIG. 8 is a flow diagram including a process for determining the optimal unique axis position and gear ratio for each mirror of a mirror array (e.g., mirror array 120B shown in FIG. 7). Referring to the left side of FIG. 8, the placement and alignment of the unique axis for each individual mirror(e.g., mirror 121B-11 of FIG. 7) is found by setting the center of each mirror at a predetermined X-axis, Y-axis and Z-axis position relative to the raised solar receiver (block 210), determining normal vector values for ideal reflected beams from the center of each mirror to the raised solar receiver for a plurality (e.g., three) of sun angles (block 220), and then computing the corresponding unique pivot axis by calculating two error vector values based on the determined vector values, and then computing a cross product of the error vector values (block 230). Referring to the right side of FIG. 8, utilizing the established axis, the optimal angle of rotation and associated gear ratio are then determined for each mirror by initializing each mirror position such that when the sun is directly over the mirror array (sun=0°), the beam error is 0 meters (block 240), then determining the ideal deviation angles for each mirror for multiple sun elevation angles ranging from 0° to 90° (block 250), summing the deviation angles (block 260), and then minimizing the sum as a function of gear ratio R (block 270). Depending on which quantities (e.g. annual energy output) are to be optimized, persons skilled in the art will see that there are many ways to configure the motion control system and compute the gear ratios of each mirror, if applied, but these many ways have one thing in common: mirrors in different locations will need to sweep through different tilt angle values so that at any given moment their actual mirror normal vectors are nearest to the ideal normal vectors at that moment. Additional details regarding the method set forth in FIG. 8 are described below.

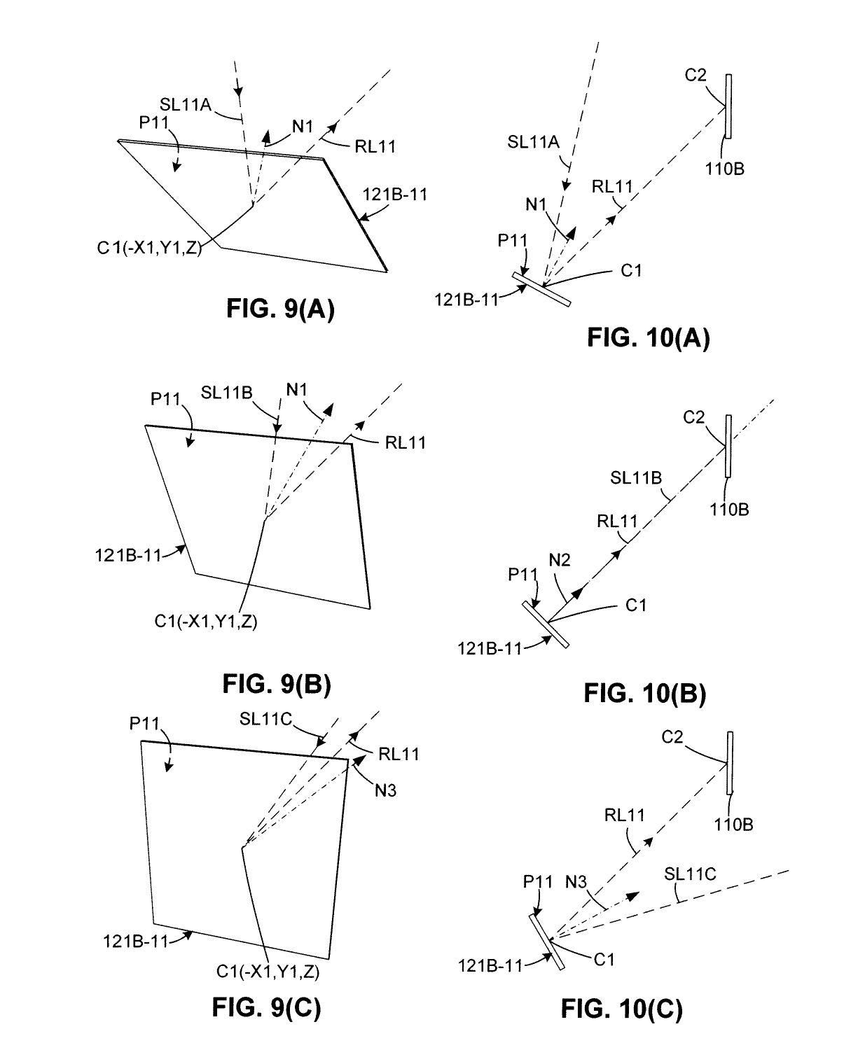

FIGS. 9(A) to 9(C) are simplified rear top perspective views respectively showing mirror 121B-11 of solar-tower system 100B (see FIG. 7) in three ideal mirror positions (orientations) determined in accordance with block 220 of FIG. 8, and FIGS. 10(A) to 10(C) are simplified side views respectively showing mirror 121B-11 in the three ideal mirror positions.

Referring to FIGS. 9(A) and 10(A), mirror 121B-11 is disposed in the first ideal mirror position when center point C1 of planar reflective surface P11 is located at the unique X-, Y- and Z-axis location (i.e., −X1, Y1 and Z) associated with mirror 121B-11, and mirror 121B-11 is oriented such that a beam SL11A (e.g., a laser beam), which is transmitted along the fixed apparent azimuth angle and a first (relatively large) elevation angle, is reflected from center point C1 to produce a reflected beam RL11 that is directed onto center region C2 of raised solar receiver 110B. Note that mirror 121B-11 is also arranged such that parallel sunlight beams reflected from any other portion of planar reflective surface P11 are reflected onto corresponding portions of raised solar receiver 110B. That is, the ideal orientation (position) of mirror 121B-11 shown in FIGS. 9(A) and 10(A) causes sunlight parallel to beam SL11 to be reflected from all portions of planar reflective surface P11 along directions parallel to beam RL11, and hence to reach raised solar receiver 110B with perfect accuracy. Note also that the first ideal orientation of FIGS. 9(A) and 10(A) is represented by a normal vector value N1, which is the vector normal to center point C1 of planar reflective surface P11 when mirror 121B-11 is in the first ideal orientation.

Referring to FIGS. 9(B) and 10(B), mirror 121B-11 is disposed in the second ideal mirror position when center point C1 is located at −X1, Y1 and Z and mirror 121B-11 is oriented such that a beam SL11B, which is transmitted along the fixed apparent azimuth angle and a second (intermediate) elevation angle, is reflected from center point C1 in the direction of reflected beam RL11 onto center region C2 of raised solar receiver 110B. Note that mirror 121B-11 must be tilted upward from the first ideal orientation (shown in FIGS. 9(A) and 10(A)) to account for the reduced sun elevation angle. The second ideal orientation of FIGS. 9(B) and 10(B) is represented by a normal vector value N2, which is the vector normal to center point C1 of planar reflective surface P11 when mirror 121B-11 is in the second ideal orientation.

Referring to FIGS. 9(C) and 10(C), mirror 121B-11 is disposed in the third ideal mirror position when center point C1 is located at −X1, Y1 and Z and mirror 121B-11 is oriented such that a beam SL11C, which is transmitted along the fixed apparent azimuth angle at a third (relatively low) elevation angle, is reflected from center point C1 in the direction of reflected beam RL11 onto center region C2 of raised solar receiver 110B. Note that mirror 121B-11 must be tilted further upward from the first and second ideal orientations to account for the low sun elevation angle of beam SL11C. The third ideal orientation of FIGS. 9(C) and 10(C) is represented by a normal vector value N3, which is the vector normal to center point C1 of planar reflective surface P11 when mirror 121B-11 is in the third ideal orientation.

Although FIGS. 9(A) to 9(C) depict ideal mirror orientations for three arbitrarily selected sun elevation angles at three points in time, it is understood that the orientation (tilt angle) of mirror 121B-11 must be essentially continuously changed throughout the daylight hours. As the sun's elevation varies from overhead down to the horizon, it is found that the set of ideal normal vectors (e.g., normal vector values N1, N2 and N3) continuously constructed for mirror 121B-11 will approximate a portion of a cone. When mirror 121B-11 is mounted to rotate about a fixed axis, these normal vectors of the mirror will sweep around the axis and form a perfect cone. By choosing the rotational axis wisely, that perfect cone and the set of ideal normal vectors are very near each other. In a specific embodiment, if a mirror is driven by its own motor and controller, and is therefore free to pivot to the best tilt angle θₘ at any given moment, then the normal vector can be positioned nearest to the ideal normal vector for that moment. In this manner, sunlight hence reflected will be as close to RL11 as achievable by the turntable concept utilized in the present invention (i.e., the minimal deviation to the receiver is achieved at any moment and at all times).

While there are many ways to choose the three normal vector values utilized in the calculation of the unique pivot axis for a given mirror, the presently preferred embodiment involves choosing vectors where the corresponding sun's elevation is highest occurring at the latitude of where the turntable is installed, or by choosing the vectors where the power system overall is most productive, or by choosing the vector where calibration is most reliable, or a combination of these and other prioritized conditions.

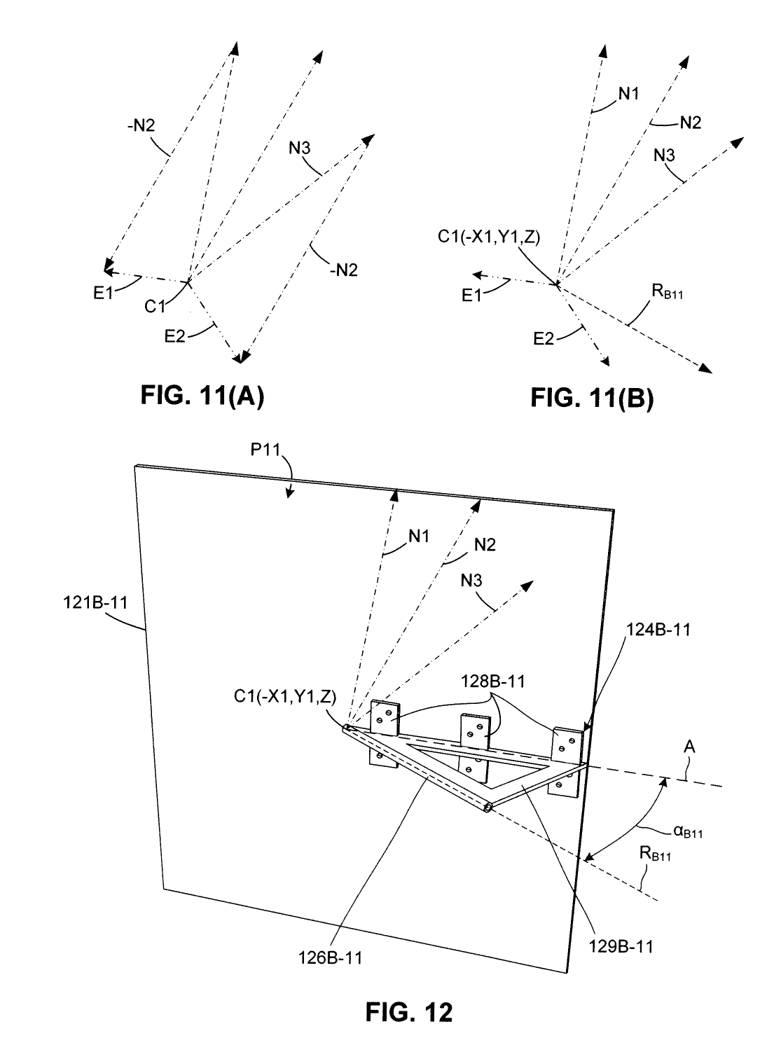

FIGS. 11(A) and 11(B) are vector diagrams illustrating the calculation of the unique pivot axis for mirror 121B-11 according to block 230 FIG. 8. Referring to FIG. 11(A), the ideal normal vector values N1, N2, N3 (which extend from common center point C1), which are determined as set forth above, are used to generate two error vectors E1 and E2, where error vector E1 is computed by subtracting normal vector value N2 from normal vector value N1 (i.e., E1=N1−N2), and error vector E2 is computed by subtracting normal vector value N2 from normal vector value N3 (i.e., E2=N3−N2). As indicated in FIG. 11(B), unique pivot (rotational) axis R_{B11} is then computed as the cross product of error vectors E1 and E2 (i.e., R_{B11}=E1×E2). Note that by rotating mirror 121B-11 around the computed axis R_{B11} while maintaining center point C1 at location −X1,Y1,Z, mirror 121B-11 can precisely pivot to the ideal orientations associated with normal vector values N1, N2 and N3. That is, when sunlight is received at the corresponding sun elevation angles described above with reference to FIGS. 9(A) to 9(C), the reflected sunlight will achieve zero deviation at the three mirror tilt angles represented by normal vector values N1, N2 and N3. Note also that the typical rotational axis computed in this manner is not parallel to the X-axis, and in fact not even horizontal (i.e., parallel to the X-Y plane). Generally the typical axis will dip below horizontal with the end pointing towards the Y-axis.

FIG. 12 is a simplified rear top perspective view showing mirror 121B-11 with an angled bracket 124B-11 produced in accordance with an embodiment of the present invention. Angled bracket 124B-11 includes one or more attachment (first) portions 128B-11 that are connected to a backside surface of mirror 121B-11, a tubular axis (second) portion 126B-11 that is aligned with unique pivot axis R_{B11}, and a brace (third) portion 129B-11 that serves to maintain tubular axis (second) portion 126B-11 at an orientation angle α_{B11} relative to planar reflective surface P11. Note that orientation angle α_{B11} represents the acute angle at which unique pivot axis R_{B11}, intersects the plane defined by planar reflective surface P11.

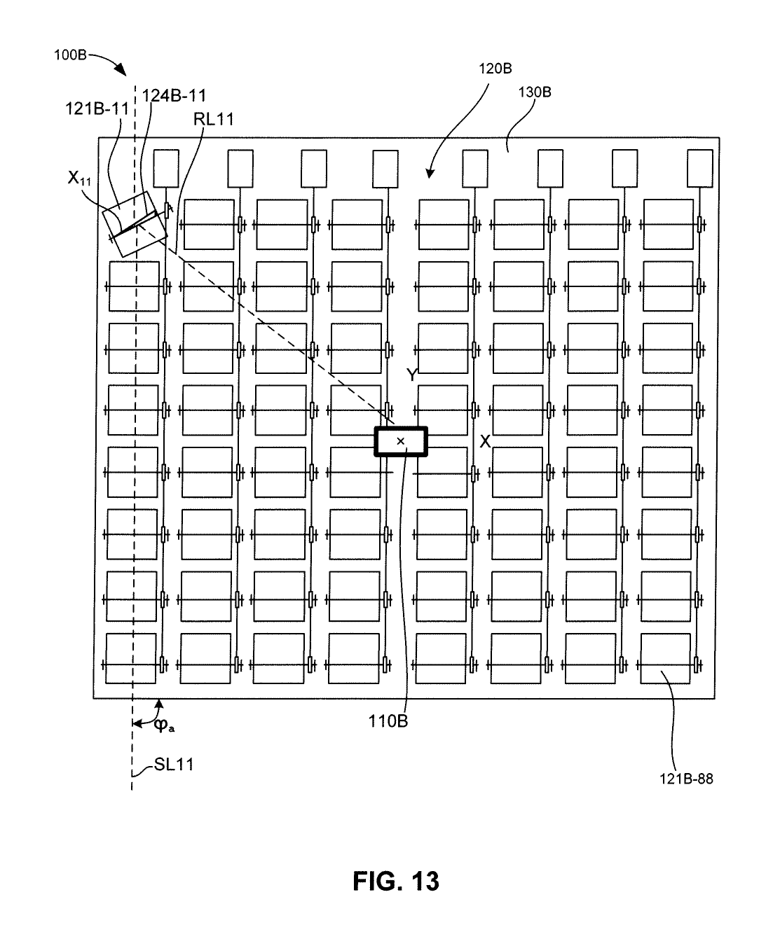

FIG. 13 is a simplified top plan view showing solar-tower system 100B with mirror 121B-11 operably mounted onto platform 130B by way of bracket 124B-11 and corresponding support mechanisms (not shown) that constrain mirror 121B-11 to pivot around unique pivot axis R_{B11} into each of the determined plurality of ideal mirror orientations (positions) described above with reference to FIGS. 9(A) to 9(C). When properly mounted, substantially all sunlight SL11 directed along fixed apparent azimuth angle φₐ onto mirror 121B-11 is redirected parallel to reflected beam RL11 onto raised solar receiver 110B. The process described above for determining the unique orientation and pivot axis for mirror 121B-11 is then repeated for each remaining mirror of mirror array 120B.

According to an aspect of the embodiment mentioned above, a gear set associated with each mirror in mirror array 120B (FIG. 7) is connected to the shared power transfer mechanism (drive shaft) by way of a gear mechanism having a unique gear ratio determined in accordance with each mirror's position relative to raised solar receiver 110B, whereby each group of mirrors driven from a single actuation (i.e., motor/drive shaft combination) that will pivot at a unique rotational rate, which when couple to the unique gear ratio, will result in different angles of rotations for each mirror, where each angle of rotation is optimized for reflecting sunlight to raised solar receiver 110B. The gear ratio R is defined such that mirrors on the Y-axis (i.e. the mirror, the sun, and the receiver are all within the same vertical plane) all have a gear ratio of R=1. It is well known that to keep the reflected sunlight aiming at the receiver, these mirrors only need to pivot around an axis parallel to the X-axis of an angular change θₘ=0.5θₛ. Using this process, the solar elevation tracking controller is able to accurately reflect sunlight from each mirror onto the raised solar receiver simply by individually controlling each mirror's pivot position in accordance with the sun's elevation angle. When all the initial position and gear ratio provisions above are applied, hundreds or thousands of mirrors can be controlled to reflect the sun's beams onto the raised solar receiver from dawn to dusk using a relatively small number of actuators. By moving the entire mirror array using a small number of motors and tracking systems, the present invention significantly reduces system costs. Also, by using many small mirrors, the reflected sunlight achieves higher concentration levels, thus reaching higher temperatures on the solar receiver. By confining the path of the sun to the fixed apparent azimuth angle φₐ at all times during daylight hours, the mirrors of the mirror array can be cleverly placed to minimize shadowing and blocking, which are the two major factors of heliostat systems that prevent portion of sunlight from reaching the receiver. More mirrors potentially can be packed to collect as much sunlight as possible given a certain platform a real coverage. Given the cost savings we have an opportunity to reach a LCOS of below 5¢/kWhr while making high utilization of available land. There are other weighting schemes that favor sun elevation angles that are occurring more often on an annual basis, or other weighting schemes that ultimately maximize annual energy production.

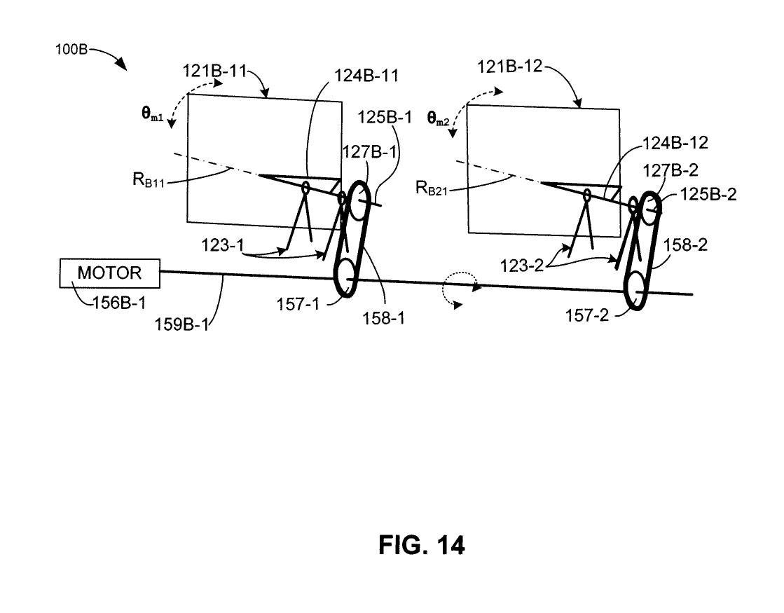

FIG. 14 is a simplified diagram showing a portion of system 100B including motor 156B-1 and mirrors 121B-11 and 121B-12. Referring to FIG. 14, drive shaft 159B-1 is operably connected to and rotated by motor 156B-1, and drive gears 157-1 and 157-2 are fixedly connected to drive shaft 159B-1 such that rotation of drive shaft 159B-1 causes rotation of drive gears 157-1 and 157-2. In addition, each mirror 121B-11 and 121B-12 has a corresponding axles 125B-1 and 125B-2 that are fixedly connected to associated driven gears 127B-1 and 127B-2 and to associated angled brackets 124B-11 and 124B-12 such that rotation of driven gears 127-1 and 127-2 respectively causes pivoting (tilting) of mirrors 121B-11 and 121B-12 by way of axles 125B-1 and 125B-2 and angled brackets 124B-11 and 124B-12. Note that axles 125B-1 and 125B-2 are respectively positioned on unique pivot axes R_{B11} and R_{B12}, and are operably engaged with angled brackets 124B-11 and 124B-12 such that mirrors 121B-11 and 121B-12 are constrained to rotate around axles 125B-1 and 125B-2. Rotational force is transferred from drive shaft 159B-1 to axles 125-1 and 125-2, respectively, by way of transfer mechanisms 158-1 and 158-2 (e.g., chains or belts) that are operably trained around drive/driven gear pairs 157-1/127-1 and 157-2/127-2, respectively. In accordance with the present aspect, drive/driven gear pairs 157-1/127B-1 and 157-2/127B-2 form gear mechanisms having a unique gear ratio determined in accordance with their associated mirror's position relative to raised solar receiver 110B. That is, the size (diameter) of drive gear 157-1 and driven gear 127B-1 are set in a first ratio corresponding to the pivot angle needed for mirror 121B-11, and the size (diameter) of drive gear 157-2 and driven gear 127B-2 are set in a second ratio corresponding to the pivot angle needed for mirror 121B-12. Because mirror 121B-11 is positioned further from raised solar receiver 110B than mirror 121B-12 (see FIG. 7(A)), the range of rotation of mirror 121B-12 is greater than the rotational range of mirror 121B-11. In order to accommodate this different rotational range, the gear ratio associated with gear pairs 157-1/127B-1 and 157-2/127B-2 are set according to know techniques such that mirrors 121B-11 and 121B-12 undergo different angles of rotations when driven by the single actuation formed by motor 156B-1 and drive shaft 159B-1. By optimizing the angle and range using, for example, the method described below with reference to FIG. 9, the angles of rotation of mirrors 121B-11 and 121B-12 may be optimized for reflecting sunlight onto raised solar receiver 110B throughout the daylight hours.

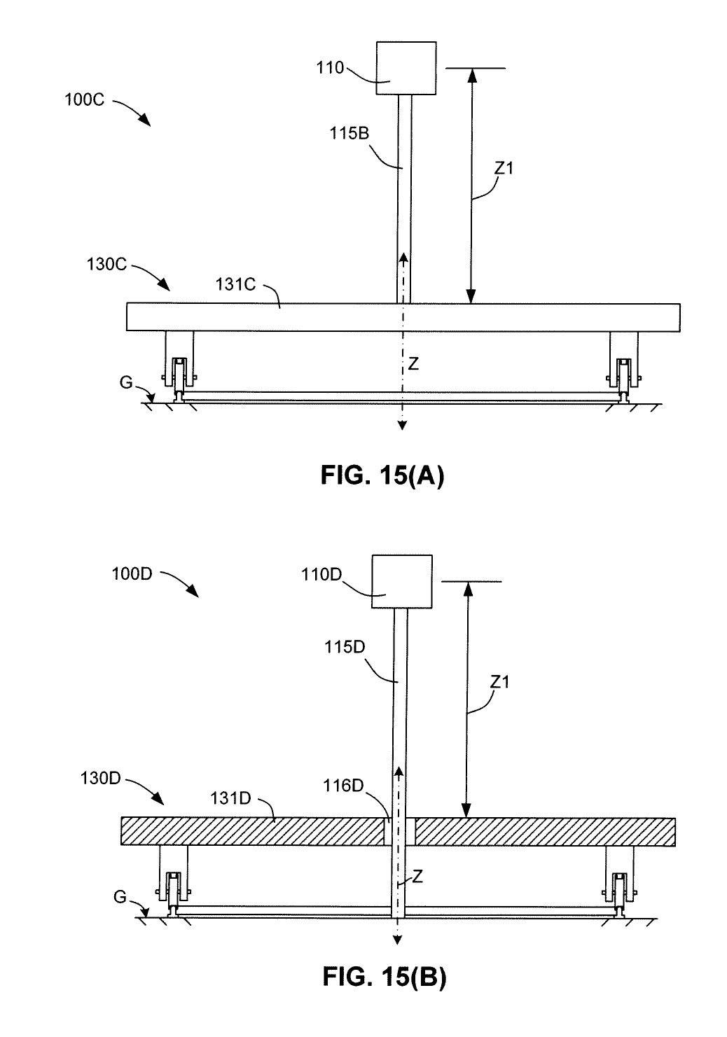

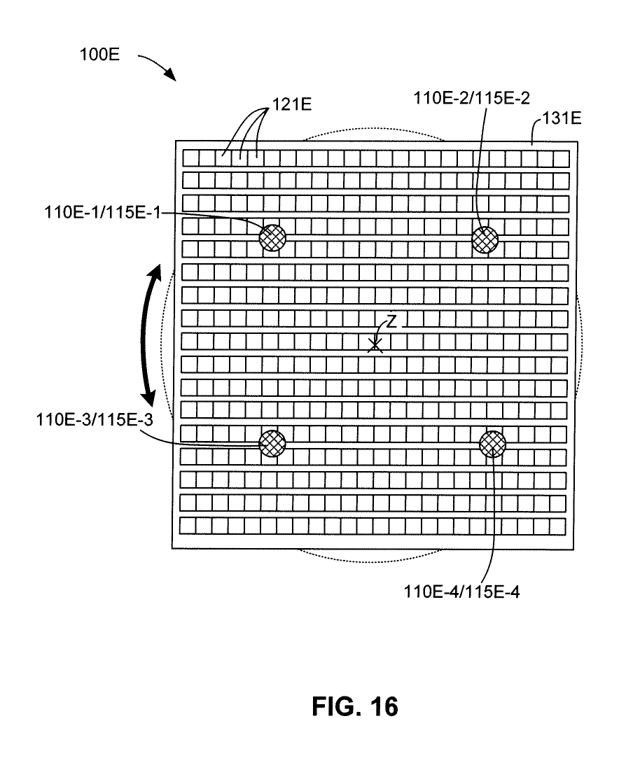

FIGS. 15(A) and 15(B) are simplified side views showing alternative solar-tower power systems according to alternative specific embodiments of the present invention. In each of these figures, the tower (e.g., tower 115C shown in FIG. 15(A)) is an elongated structure that extends along (i.e., collinear with) the rotational axis Z defining the center of rotation of the mirror array (not shown), thereby maintaining the raised solar receiver (e.g., raised receiver 110C shown in FIG. 15(A)) substantially on the rotational axis Z for all rotational angles of the mirror array. In the specific embodiment shown in FIG. 15(A), solar-tower power system 100C includes a tower 115C that is mounted on base structure 130C (i.e., fixedly connected to roundabout platform 131C) such that raised solar receiver 110C rotates at the same rate as the mirror array (not shown), which is disposed on roundabout platform 131C in the manner described above. FIG. 15(B) shows solar-tower power system 100D according to another specific embodiment in which a tower 115D extends through a central opening 116D formed in roundabout platform 131D and is fixedly attached to ground G, which also serves as the support surface upon which base structure 130D is rotatably disposed in a manner similar to that described above. In this embodiment, base structure 130D rotates relative to the tower 115D and the raised solar receiver 110C. In another alternative embodiment shown in FIG. 16, a solar-tower power system 100E includes four towers 115E-1 to 115E-4, each respectively having a solar receiver 110E-1 to 110E-4 mounted thereon, wherein each of the towers 115E-1 to 115E-4 is fixedly attached to the base structure 130E away from the rotational axis Z. Note that mirrors 121E in this case are optimized to reflect light onto one of the four corresponding solar receiver 110E-1 to 110E-4. Each of the arrangements described with reference to FIGS. 15(A), 15(B) and 16 maintains the raised solar receiver in a substantially fixed position relative to all of the mirrors for all rotational angles of the mirror array, thereby facilitating more efficient transfer of solar energy to the raised solar receiver than is possible using conventional solar-tower power systems.

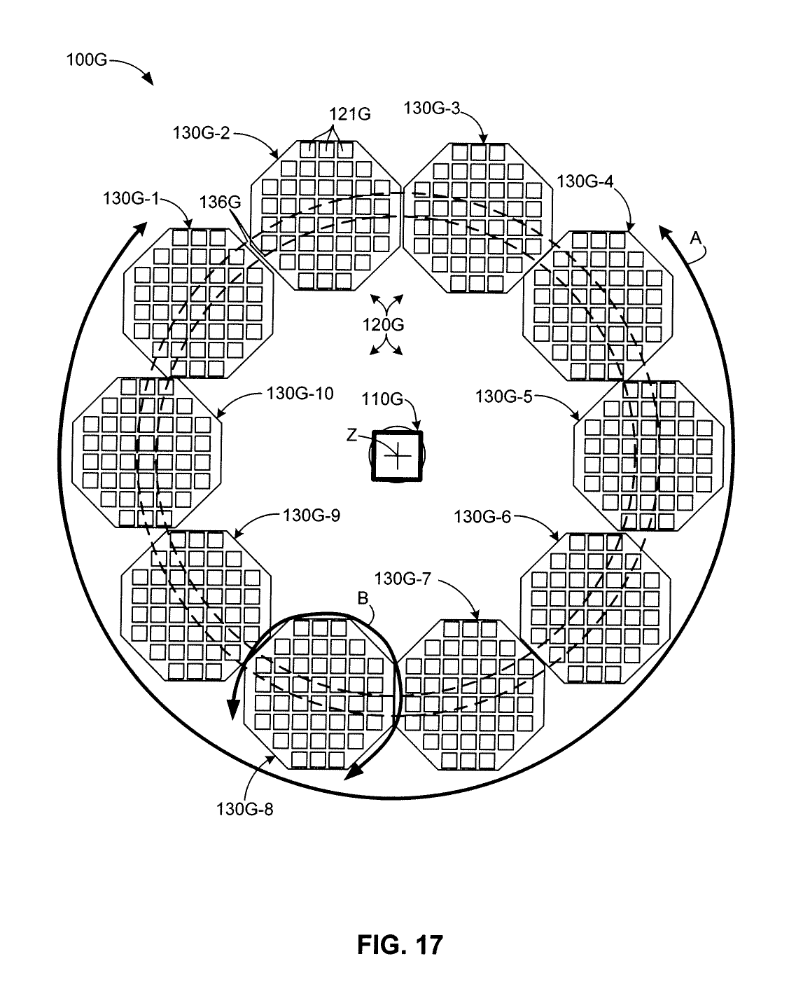

Although the present invention is described above with reference to a single roundabout platform supporting the entire mirror array, other embodiments are possible. For example, FIG. 17 shows a solar-tower system 100G according to an alternative exemplary embodiment in which the base structure includes ten separate platform sections 130G-1 to 130G-10 that are disposed to rotate as a group around a rotational axis Z, e.g., on a set of concentric rails 136G, where each of platform sections 130G-1 to 130G-10 carries a subset of mirrors 121G that collectively form mirror array 120G in the manner described above. Note that during normal operation all ten separate platform sections 130G-1 to 130G-10 rotate together as a unit around central axis Z (as indicated by large arrow A), and in addition each platform can rotate around a local axis as well (as indicated by small arrow B). This multiple platform approach addresses possible cost and engineering drawbacks associated with utilizing a single large platform to support the entire mirror array. This multiple platform approach may also be manipulated to facilitate access roads to move equipment or electricity in and out of the surrounding mirrors. That is, one platform section can be removed from a ring-shaped pattern to open a space for an access path to the centrally located tower, although the access path itself will have to move while the rest of the platforms move.

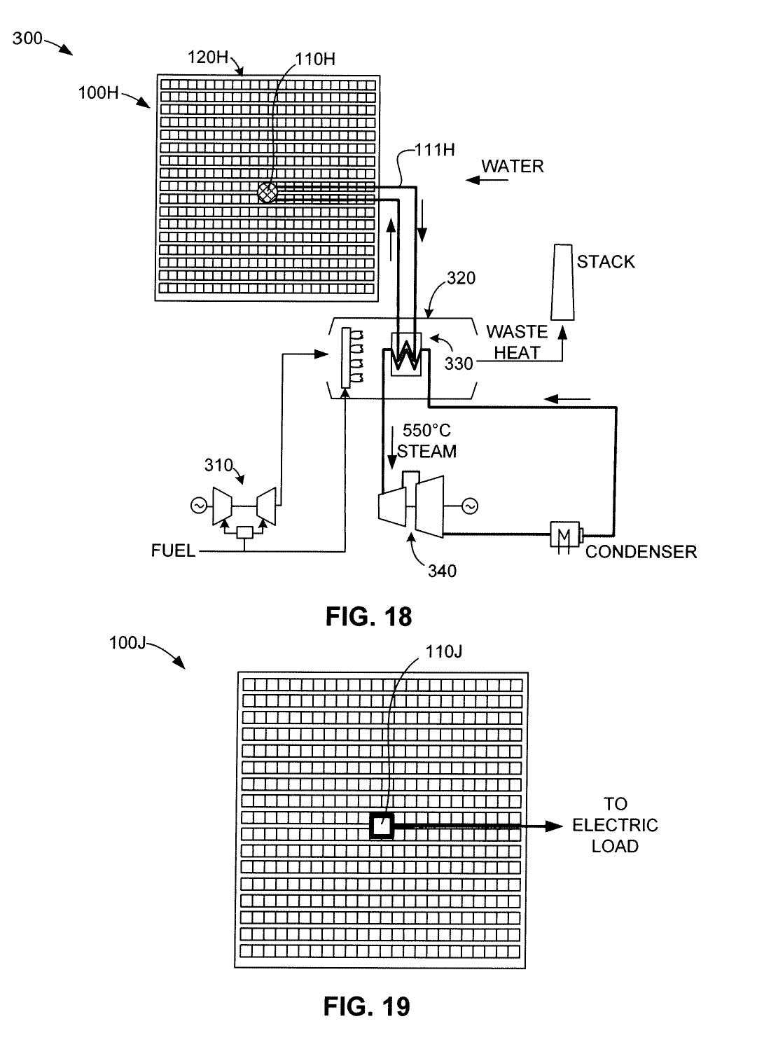

FIG. 18 is a simplified diagram showing a co-generation power plant 300 utilizing both a solar-tower system 100H produced according to any of the embodiments described above, and a conventional natural gas heat generator 310 to generate steam in a conventional steam production facility 320 for driving a steam turbine 340. In accordance with this embodiment of the present invention, solar-tower system 100H includes a mirror array 120H is disposed in a 100 meter by 100 meter area next to steam production facility 320, and a heat-exchange-type solar receiver 110H having a conduit 111H containing a heat transfer fluid that is heated by the sunlight concentrated by mirror array 120H in the manner described above. The heated transfer fluid is then transferred by conduit 111H to a heat exchanger 330 disposed inside steam production facility 320. Steam production facility 320 is configured to utilize both solar-tower system 100H and natural gas heat generator 310 to generate super-heated steam at 550° C. that drives steam turbine 340, thus generating electricity. During bright sunny days, sufficient heat is generated by solar-tower system 100H such that 550° C. steam is generated is generated by steam generator 320 without assistance from natural gas heat generator 310. At night (or on cloudy days when solar energy is insufficient to achieve steam at 550° C.), natural gas heat generator 310 is implemented to generate the desired steam temperature. The solar-tower systems of the present invention are ideally suited for use in such co-generation power plant arrangements because they combine a clear set of upfront costs, low land use, low maintenance costs, and highly reliable performance expectations.

Although the present invention is described above with reference to steam generation, other embodiments are possible. FIG. 19 is a partial simplified top view showing a solar-tower system 100J having a mirror array 120J disposed to reflect sunlight in the manner described above. In this embodiment, solar receiver 110J comprises a device (e.g., a photovoltaic (PV) cell or a thermoelectric cell) that directly converts the concentrated solar energy into electricity that is then transmitted by conductive wire to a designated load. This arrangement is conducive to implementing solar-tower system 100J using a smaller platform and mirror array that can be mounted, for example, on a residential rooftop. The roundabout platform configuration minimizes wind disturbance, can operate on slanted rooftops, and potentially can be lighter (less demanding to withstand wind) and cheaper to build. The strength of the platform design is also its weakness. Since it stays flat on the ground, the basic design cannot present the maximum mirror area to the sun when the sun's elevation is low. In an alternative embodiment, the platform can be tilted to a fixed tilt angle that will allow maximum mirror area to be presented to the sun. When wind picks up, the platform can be lowered to the horizontal position but continue to track and produce electricity although at a lower output (that is consistent with the sun having a lower elevation position).

Although the present invention has been described with respect to certain specific embodiments, it will be clear to those skilled in the art that the inventive features of the present invention are applicable to other embodiments as well, all of which are intended to fall within the scope of the present invention. For example, the disclosed system may be modified to include an automated cleaning system that operates every evening as the platform moves back to its starting point for the next day, the cleaning system including a stationary section where water is sprayed on all mirrors passing under a sprayer unit, and a drainage system underneath that collects, filters, stores, and reuses the water much like a car wash station. In another example, the disclosed system may be modified such that the roundabout platform floats on water, and rotates in a ring-shaped pool similar to a moat. A bridge is built over the mirror array to provide service access and bring electricity or pipe fluid into and out of the tower.

1. A method for harvesting solar energy, the method comprising:
disposing a mirror array and a solar receiver such that the plurality of flat mirrors are arranged in a low-profile pattern and are rotatable as a single unit around a rotational axis, and such that the solar receiver is located at a substantially fixed position relative to all of the plurality of flat mirrors for all rotational positions of the mirror array around a rotational axis;
adjusting a rotational position of the mirror array in accordance with the sun's azimuth angle such that sunlight is directed onto the mirror array along a fixed apparent azimuth angle at all times during daylight hours; and
individually controlling a pivot angle of each of the plurality of flat mirrors in accordance with a current sun elevation angle such that sunlight is reflected by all of the plurality of flat mirrors onto the solar receiver.

2. The method according to claim 1, wherein disposing the mirror array comprises mounting each of the plurality of flat mirrors on a base structure, and wherein adjusting a rotational position of the mirror array comprises:
detecting a sun azimuth angle,
generating control signals in response to the detected sun azimuth angle, and
rotating the base structure around the rotational axis in accordance with the control signals.

3. The method according to claim 2,
wherein disposing the mirror array comprises mounting each of the plurality of flat mirrors on a corresponding support structure that is fixedly connected to the base structure such that each of the plurality of flat mirrors is pivotable around a corresponding unique pivot axis relative to its support structure, and
wherein individually controlling a pivot angle of each of the plurality of flat mirrors comprises:
detecting a sun elevation angle,
generating control signals in response to the detected sun elevation angle, and
pivoting each of the plurality of flat mirrors around its corresponding pivot axis in accordance with the control signals.

4. The method according to claim 1,
wherein disposing the mirror array comprises mounting each of the plurality of flat mirrors on a corresponding support structure that is fixedly connected to a base structure such that each of the plurality of flat mirrors is pivotable around a corresponding unique pivot axis relative to its support structure, and
wherein individually controlling a pivot angle of each of the plurality of flat mirrors comprises:
detecting a sun elevation angle,
generating control signals in response to the detected sun elevation angle, and
pivoting each of the plurality of flat mirrors around its corresponding unique pivot axis in accordance with the control signals.

5. The method according to claim 1, wherein disposing the mirror array comprises:
determining an associated plurality of ideal mirror positions for each mirror of the plurality of flat mirrors such that said each mirror reflects sunlight from a corresponding unique sun elevation angle onto the raised solar receiver in each of the associated plurality of ideal mirror positions,
computing the corresponding unique pivot axis associated with said each mirror using a plurality of normal vector values, each normal vector value being perpendicular to the planar reflective surface of said each mirror when said each mirror is in an associated mirror position of said plurality of ideal mirror positions, and
mounting each of the plurality of flat mirrors on a base structure such that said each mirror is constrained to pivot around the computed corresponding unique pivot axis into each of the determined plurality of ideal mirror positions.

6. The method according to claim 5, wherein mounting each of the plurality of flat mirrors comprises connecting an angled bracket onto said each mirror having a first portion disposed parallel to the planar reflective surface of said each mirror and a second portion intersecting the planar reflective surface of said each mirror at a corresponding acute orientation angle.

7. The method according to claim 5,
wherein arranging the plurality of flat mirrors comprises connecting two or more mirrors of said plurality of flat mirrors to a single drive motor by way of a drive member,
wherein individually controlling a pivot angle of each of the two or more mirrors comprises actuating said motor.

8. The method according to claim 7,
wherein connecting said two or more mirrors of said plurality of flat mirrors to a single drive motor comprises:
connecting a drive shaft having a plurality of driving gears to said single drive motor; and
connecting each said two or more mirrors to a driven gear that is operably connected to an associated drive gear of said plurality of drive gears such that rotation of said associated drive gear by said drive shaft causes rotation of said driven gear, whereby said each flat mirror is rotated said unique predetermined distance around its corresponding axis.

9. The method according to claim 5,
wherein disposing the mirror array comprises arranging the plurality of flat mirrors in rows and columns, and connecting two or more mirrors of said plurality of flat mirrors disposed in each column to a single drive motor by way of a drive member, and
wherein individually controlling a pivot angle of each of the two or more mirrors comprises actuating said motor.

10. The method according to claim 1, wherein disposing the mirror array and the solar receiver comprises disposing the solar receiver is on a tower that extends along the rotational axis such that the solar receiver is disposed above the plurality of flat mirrors.

11. The method according to claim 10,
wherein disposing the mirror array and the solar receiver comprises disposing both the mirror array and the tower on a base structure, and
wherein adjusting the rotational position of the mirror array in accordance with the sun's azimuth angle comprises rotating the base structure such that both the mirror array and the solar receiver rotate around the rotational axis.

12. The method according to claim 10,
wherein disposing the mirror array and the solar receiver comprises disposing the mirror array on a base structure, that is rotatably disposed on a support surface, and disposing the tower directly on the support surface such that the tower extends through an opening defined in said base structure, and
wherein adjusting the rotational position of the mirror array in accordance with the sun's azimuth angle comprises rotating the base structure such that the mirror array rotates around the rotational axis relative to the solar receiver.

13. The method according to claim 1, wherein adjusting the rotational position of the mirror array in accordance with the sun's azimuth angle comprises rotating the mirror array in only one of a counterclockwise and a clockwise direction during daylight hours.

14. The method according to claim 1,
wherein disposing said mirror array comprises mounting said plurality of flat mirrors on a plurality of platforms such that a group of said plurality of flat mirrors is disposed on each of said plurality of platforms; and
wherein adjusting the rotational position of the mirror array comprises rotating the plurality of platforms as a unit around the rotational axis.

15. The method according to claim 1,
wherein the solar receiver comprises a conduit containing a heat transfer fluid, and
wherein the method further comprises transferring said heat transfer fluid from the solar receiver to an external heat exchange system.

16. The method according to claim 1,
wherein the solar receiver comprises a photovoltaic cell, and
wherein the method further comprises transferring electricity from the solar receiver to an external load.

17. A method for harvesting solar energy using a solar-tower system including a raised solar receiver and mirror array comprising a plurality of flat mirrors, each flat mirror being selectively pivotable into a corresponding pivot angle around a corresponding unique pivot axis relative to a corresponding support structure, the method comprising:
disposing the mirror array and solar receiver such that the plurality of flat mirrors are rotatable as a single unit around a rotational axis and such that the solar receiver is located at a substantially fixed position relative to all of the plurality of flat mirrors all rotational positions of the mirror array;
adjusting the base structure's rotational position in accordance with the sun's azimuth angle such that sunlight is directed onto the mirror array from a fixed apparent azimuth angle at all times during daylight hours; and
individually controlling the pivot angle of each of the plurality of flat mirrors in accordance with a current sun elevation angle such that sunlight is reflected by all of the plurality of flat mirrors onto the solar receiver.

18. A method for harvesting solar energy using a solar-tower system co-generation power plant, the co-generation power plant including a gas heat generator and a solar-tower system operably coupled to a steam generator, and a steam generator connected to receive steam from the steam generator, wherein the method comprises:
utilizing the solar-tower system to generate steam in the steam generator during daylight hours; and
utilizing the gas heat generator to generate steam in the steam generator during nighttime hours,
wherein utilizing the solar-tower system comprises:
disposing a mirror array and a solar receiver such that the plurality of flat mirrors are rotatable as a single unit around a rotational axis and such that the solar receiver is located at a substantially fixed position relative to all of the plurality of flat mirrors for all rotational positions of the mirror array around a rotational axis;
adjusting a rotational position of the mirror array in accordance with the sun's azimuth angle such that sunlight is directed onto the mirror array along a fixed apparent azimuth angle at all times during daylight hours; and
individually controlling a pivot angle of each of the plurality of flat mirrors in accordance with a current sun elevation angle such that sunlight is reflected by all of the plurality of flat mirrors onto the solar receiver; and
transmitting a heat transfer fluid from the solar receiver to the steam generator.
